(19) United States
(12) Patent Application Publication
(10) Pub. No.: US 2024/0337681 A1
(43) Pub. Date: Oct. 10, 2024

(54) MOUNTING SYSTEM, AND METHODS THEREOF

(71) Applicant: Ferroelectric Memory GmbH, Dresden (DE)

(72) Inventors: Michael BATHON, Dresden (DE); Alberto CAMPISI, Cornate d'Adda (IT)

(21) Appl. No.: 18/296,884

(22) Filed: Apr. 6, 2023

(51) Int. Cl. G01R 31/26; G01R 1/04; H01L 21/683

(52) U.S. Cl. CPC G01R 31/2601; G01R 1/0408; H01L 21/6838

(57) ABSTRACT

Various aspects relate to a mounting system, that may include a chuck and/or an adapter, and to a method to process a plurality of coupons using a processing tool. The method may include: positioning a first coupon of the plurality of coupons in a first holding area of a carrier plate and positioning a second coupon of the plurality of coupons in a second holding area of the carrier plate, supplying a vacuum to a first recess structure in the carrier plate defining the first holding area to fixate the first coupon covering the first recess structure and supplying a vacuum to a second recess structure in the carrier plate defining the second holding area to fixate the second coupon covering the second recess structure, and sequentially processing the first coupon and the second coupon while both the first coupon and the second coupon are mounted on the carrier plate.

### TECHNICAL FIELD

Various aspects relate to a mounting system, that may include a chuck and/or an adapter, and to a method to process a plurality of coupons using a processing tool.

### BACKGROUND

In general, various processing techniques are known for semiconducting materials. Each processing technique may include a plurality of process parameters and each of the plurality of process parameters may influence the resulting electrical properties of the processed semiconducting material. Therefore, it may be beneficial to determine the influence of each parameter to the resulting electrical properties of the processed semiconducting material. However, conventional probing devices may only be configured to measure the electrical property of a whole semiconducting material wafer, which may lead to high production costs, or of a single piece of the semiconducting material, which may lead to long total testing times.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIGS. 1A and 1B illustrate a mounting concept of a wafer chuck;

FIGS. 1C to 1E illustrate a mounting system according to various aspects;

FIGS. 2A to 2D illustrate a mounting system according to various aspects;

FIGS. 3A to 3G illustrate a mounting system according to various aspects;

FIGS. 4A and 4B illustrate a mounting system according to various aspects including one or more covers;

FIG. 4C illustrates a mounting system according to various aspects including an alignment pattern;

FIGS. 5A to 5E illustrate or show different aspects of a mounting system according to various aspects illustrating a single recess structure;

FIG. 6 illustrates a mounting system according to various aspects including a temperature control system;

FIGS. 7A to 7E illustrate a mounting system 100 according to various aspects that is formed as a coupon adapter;

FIG. 8A illustrates a photograph of a wafer chuck;

FIG. 8B illustrates a photograph of the wafer chuck, wherein a mounting system is illustrated, which is used as an adapter;

FIG. 9 illustrates a coupon chuck according to various aspects; and

FIG. 10 illustrates schematically a method according to various aspects to process a plurality of coupons using a processing tool.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a memory cell, or a memory capacitor). However, it may be understood that aspects described in connection with methods may similarly apply to the devices, and vice versa.

The term “device under test” (DUT) may refer herein to one or more electronic structures such as one or more electronic components and/or one or more electronic circuits. An electronic component may refer to any electronic component such as a resistor, a transistor, a capacitor, an inductor, a diode, a memory cell (e.g., a ferroelectric memory cell), as an example. An electronic circuit may include multiple electronic components being connected to each other. An electronic circuit may refer to any electronic circuit, such as one of the following: an integrated circuit (e.g., an application-specific integrated circuit), a processor (e.g., a microprocessor), a microcontroller, a memory circuit, a memory array, a memory cell (e.g., a ferroelectric memory cell), as an example.

The term “coupon” may refer to an element that includes one or more electronic devices. In a test scenario, the so-called test “coupon” or tested “coupon” includes one or more electronic devices under test (DUT). The coupon may include any suitable material capable of carrying an electronic circuit (e.g., as bulk material). For example, the coupon bulk material may include a semiconductor material, a glass, and/or a polymer, as examples. In some aspects, the coupon may be a piece of a wafer such as a wafer fragment. Furthermore, the coupon may be configured to be fixated on a vacuum chuck or on any suitable (e.g., planar) carrier plate. For example, the coupon may have at least a planar bottom surface such that the coupon may be vacuum-fixated with its planar bottom surface on a vacuum chuck or on any suitable (e.g., planar) carrier plate. For example, a vacuum-fixated coupon may be fixated at a carrier plate by a vacuum that causes a suction force. For example, a coupon may have an irregular shape, e.g., with respect to its perimeter (e.g., to an outer margin). For example, a coupon may have more than 3 vertices, e.g., 4 vertices, 5 vertices, 6 vertices, 7 vertices, or more than 7 vertices. For example, an outer margin of a coupon may have a section in which the outer margin of the coupon may be substantially straight. For example, an outer margin of a coupon may have a section in which the outer margin of the coupon may be substantially curved. For example, an outer margin of a coupon may have a section in which the outer margin of the coupon may be substantially serrated. For example, an outer margin of a coupon may have a section in which the outer margin of the coupon may be a fraction edge.

The term “fluid” may be used herein with respect to a liquid and/or a gas, e.g., a mixture of a liquid and a gas. The term “fluid-conductively connected” may be used herein with respect to nodes, lines, junctions, terminals, and the like. Herein, two elements that are “fluid-conductively connected (to each other)” may implement a volume flow of a fluid between them. The volume flow may have a laminar behavior or a turbulent behavior. For example, the two elements may include one or more terminals, regions, channels, lines, etc. Furthermore, a “fluid-conductive connection” between two elements may refer to the implementation of the connection between the two elements that allows the volume flow between the two elements. Furthermore, a fluid-conductive connection may include one or more elements that are configured to control a volume flow rate of the volume flow. The volume flow rate may refer to a velocity and/or an amount per time of the fluid flowing through the fluid-conducting connection. The fluid-conductive connection may include a line, a valve, and/or a switch for example. For example, a valve and/or a pump may be used to control the volume flow rate.

The term “line” (e.g., as used referring to a vacuum line for example) may refer herein to a connection element having a hole that may be used to implement a fluid-conducting connection between one opening of the hole and another opening of the hole. For example, a line may include (e.g., may be) a pipe, a hose, and/or a tube as an example.

The term “vacuum” may refer herein to a gaseous pressure that is less than a gaseous pressure (e.g., ambient pressure) around the measurement system. For example, at 20° C. a gaseous pressure between 1050 mbar and 1 mbar may be referred to as a low vacuum or rough vacuum. For example, a gaseous pressure (e.g., measured or normalized to room temperature, e.g., 20° C.) between 1 mbar and 1·10⁻³ mbar may be referred to as a medium vacuum or fine vacuum and between 1·10⁻³ mbar and 1·10⁻⁸ mbar as a high vacuum. A volume flow that is intended to create a vacuum may also be referred to as a “vacuum flow”. An apparatus that is configured to create a vacuum may be referred herein as a “vacuum supply system”. A “vacuum supply of an element” may refer herein to a provision of the element with a vacuum, e.g., reducing a gaseous pressure within the element.

The term “prober” refers to robotic equipment that may allow testing multiple DUTs on a coupon by placing the coupon in a precise position with respect to the X-Y-Z-axis. This may allow for sequential interfacing of each single DUT to the tester.

The term “chuck” may refer to a moveable part of the prober, which may keep the wafer (or as described herein in accordance with various embodiments, the coupons) in place by a vacuum suction. In one or more aspects, a wafer chuck may refer herein to a chuck that is configured to hold a single wafer at the same time (e.g., a conventional standard chuck can be used in this case as an example). Such a wafer chuck may have a carrier plate that is configured to hold a single wafer. The respective wafer may be coaxially aligned on the wafer chuck and may be fixated by one or more vacuum traces. The one or more vacuum traces are aligned within a wafer chuck plate in a substantially rotationally symmetric configuration.

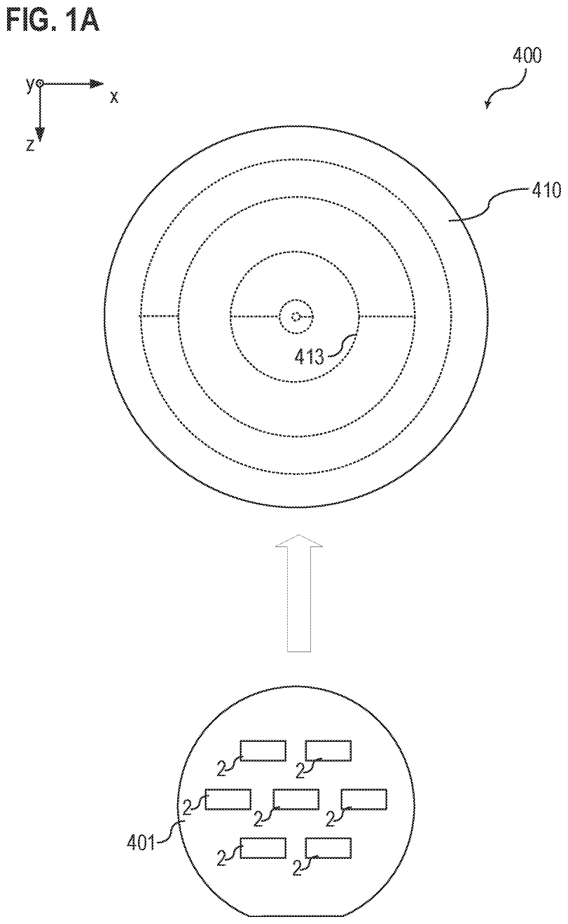

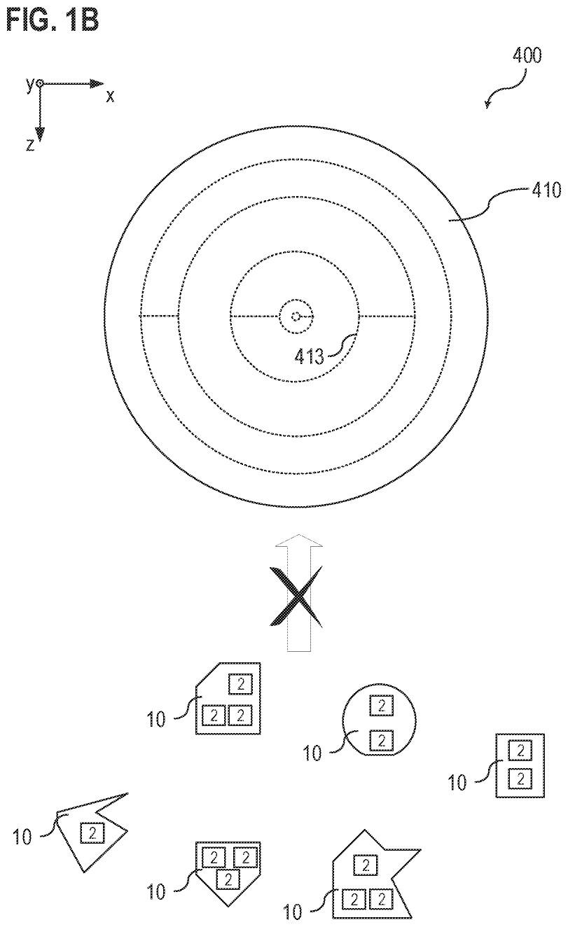

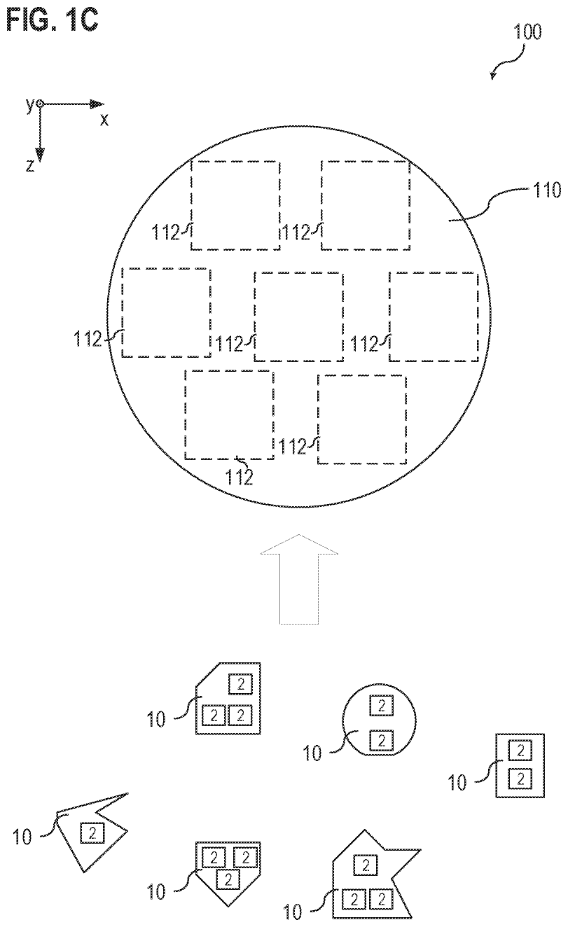

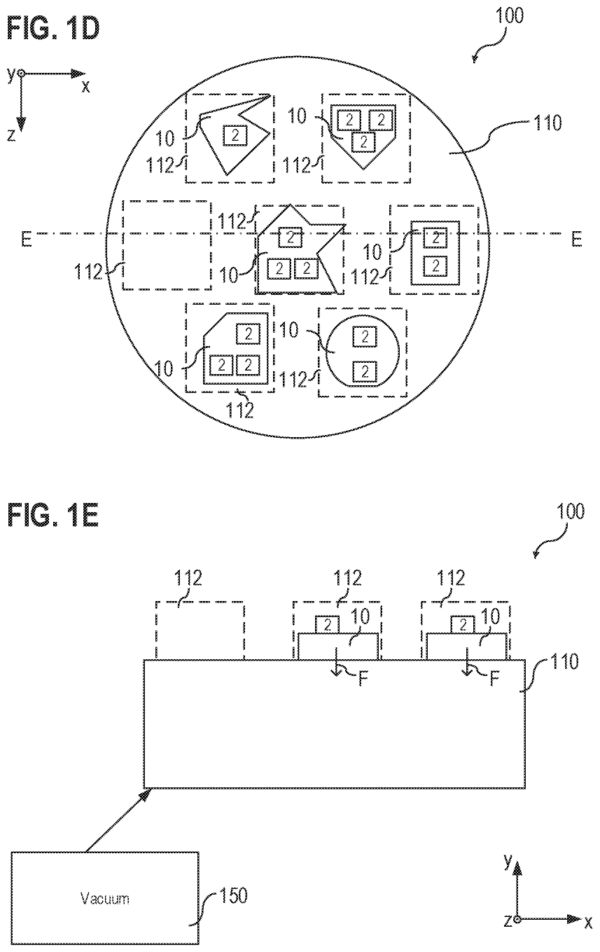

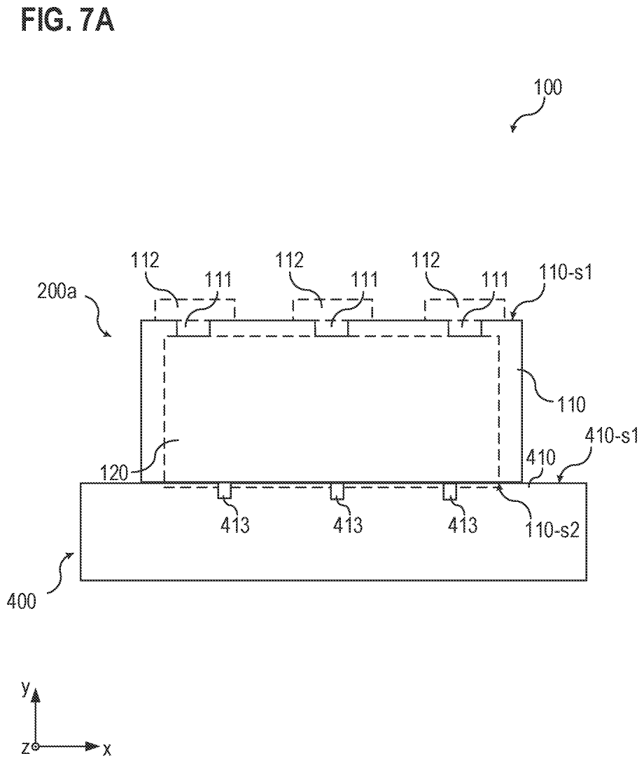

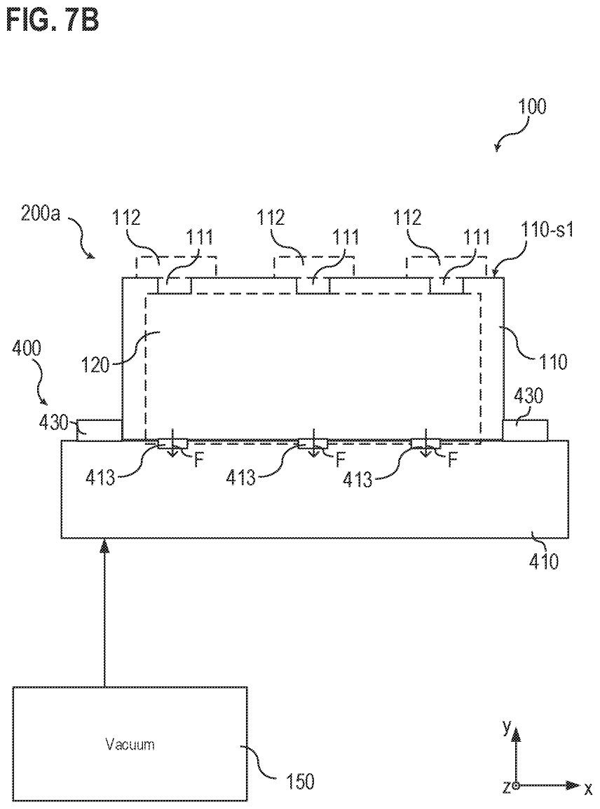

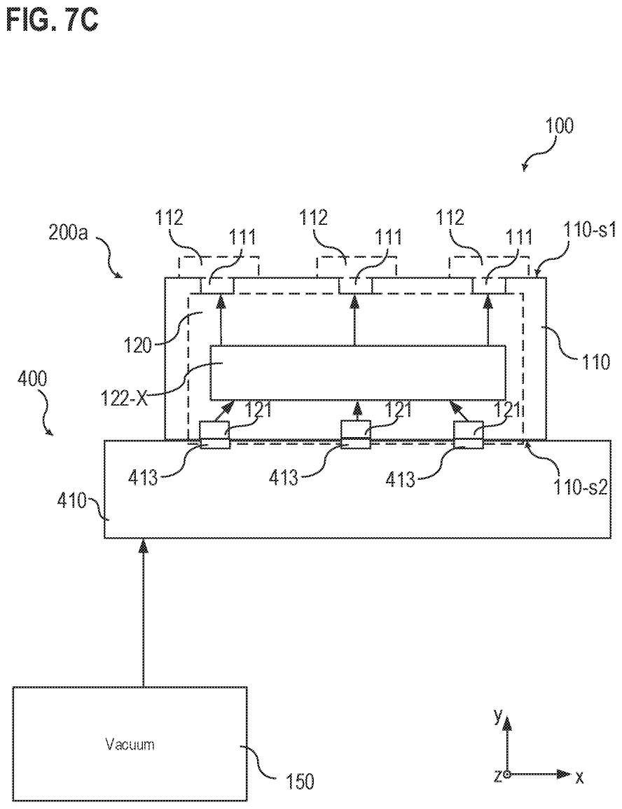

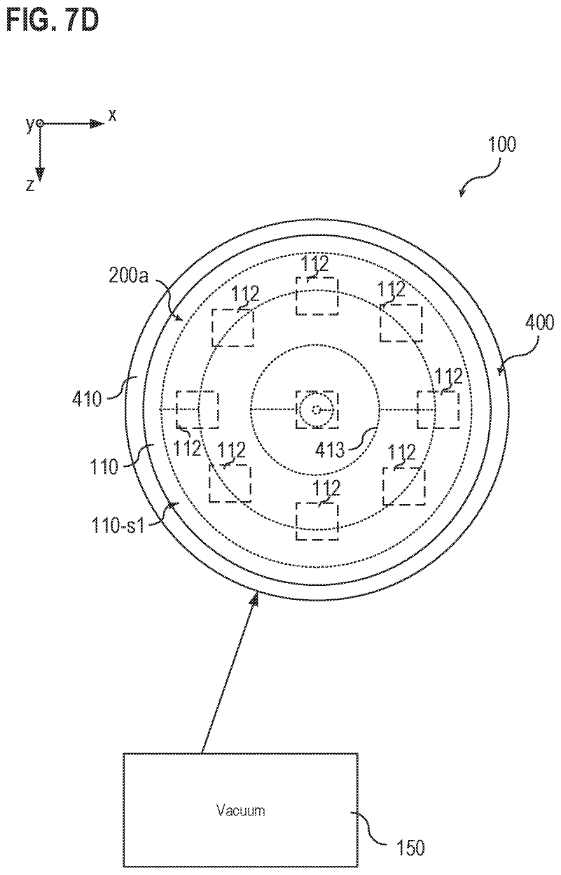

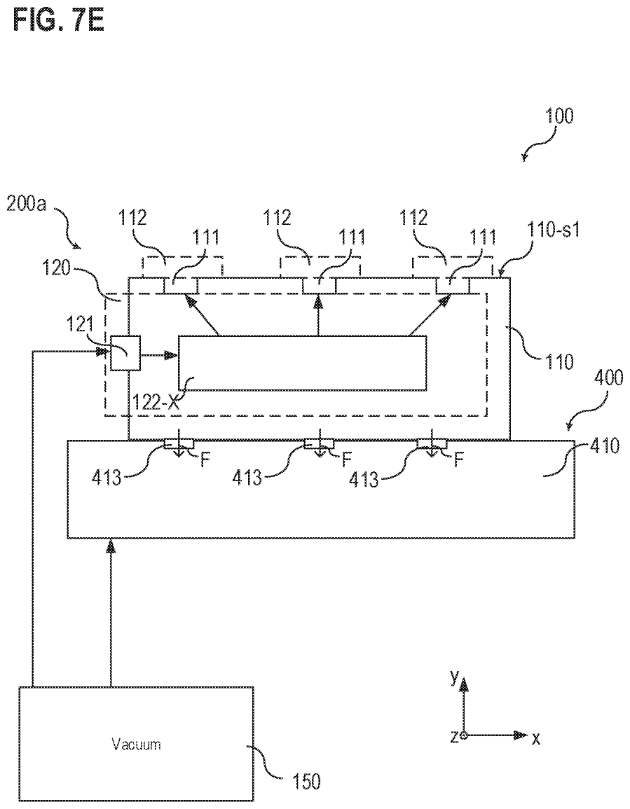

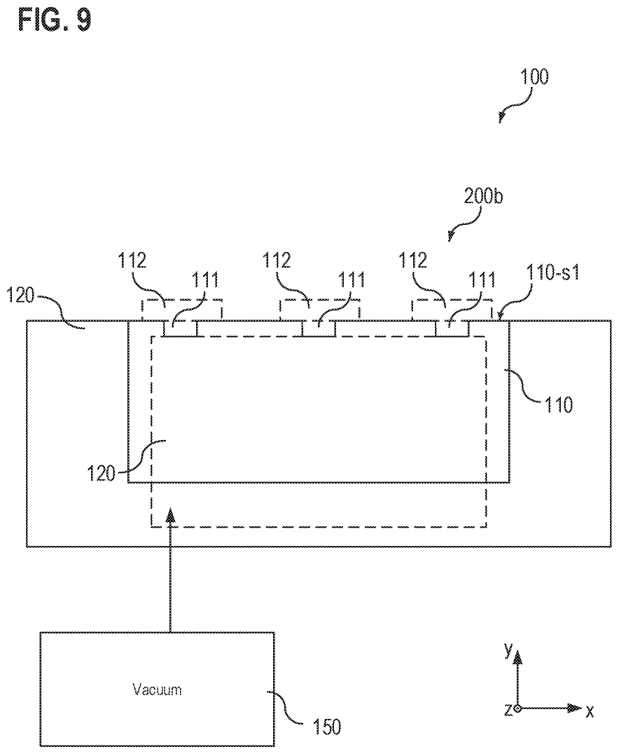

Therefore, to allow for processing (e.g., testing) of various coupons with such a wafer chuck at the same time, which cannot be realized via a wafer chuck (see, for example, FIGS. 1A and 1B), a mounting system may be used as described herein. According to various aspects, the mounting system is configured to hold various coupons at the same time. This allows for processing (e.g., testing) of various coupons at the same time. In or more aspects, the mounting system may include (e.g., may be configured as or may be) an adapter, referred to herein as a coupon adapter, to be mounted on a wafer chuck (see, for example, FIGS. 7A to 7E). In one or more other aspects, the mounting system may include (e.g., may be configured as or may be) a chuck, referred to herein as coupon chuck (see, for example, FIG. 9).

FIG. 1A and FIG. 1B illustrate a mounting concept of a wafer chuck 400. The wafer chuck 400 may include a carrier plate or a chuck plate 410, e.g., a single wafer carrier plate to mount a single wafer 401. The carrier plate or chuck plate 410 of the wafer chuck 400, referred to, for example, as a chuck plate 410, e.g., as shown in FIG. 1A and FIG. 1B, may be configured as known from standard devices, e.g., as included in conventional standard probers. The wafer chuck plate 410 may include one or more vacuum traces 413 that may be used to fixate the single wafer 401 on the wafer chuck plate 410. Furthermore, a distribution of the one or more vacuum traces 413 on the wafer chuck plate 410 may define a radius of a wafer, which may be fixated on the wafer chuck plate 410. For example, the one or more vacuum traces 413 may be arranged in different forms (e.g., may include several rings) to allow for fixating one of multiple wafers, wherein each wafer has a radius out of a predefined group of radiuses. The single wafer 401 may include one or more devices under test 2 (DUT 2).

The wafer chuck 400 may be a part of a prober (e.g., a semiautomatic prober) that is configured to test the one or more DUT 2 of the single wafer 401. If multiple single wafers are to be tested, they may need to be tested one by one. Therefore, a first single wafer 401 of the multiple single wafers may be positioned on the wafer chuck plate 410. Afterwards, when the devices to be tested are tested, the first single wafer may be replaced by a second single wafer of the multiple single wafers including another one or more DUT 2.

FIG. 1B illustrates a wafer chuck 400 including a wafer chuck plate 410 and a plurality of coupons 10. In contrast to FIG. 1A, instead of the single wafer 401, the plurality of coupons 10 is to be tested. According to the procedure described above, this may require a long time, since each coupon of the plurality of coupons 10 has to placed, tested, and removed. Furthermore, one of the plurality of coupons 10 may have a shape which may not be appropriate to be fixated on the wafer chuck plate 410. For example, one coupon of the plurality of coupons 10 may be too small to be fixated on the wafer chuck plate 410.

FIG. 1C illustrates one or more aspects of a carrier plate 110. The carrier plate 110 may be part of a mounting system 100 according to various aspects that allow for mounting and processing (e.g., testing) of a plurality of coupons 10 at the same time. In one or more aspects, the mounting system may include a coupon chuck. In one or more other aspects, the mounting system 100 may include a coupon adapter to be mounted on a wafer chuck. Illustratively, in the case that the mounting system 100, e.g., the carrier plate 110, is used in combination with a wafer chuck 400 it may realize an adapter function to mount a plurality of coupons 10 (e.g., as a coupon adapter) instead of, for example, a single wafer that could be mounted on the wafer chuck 400.

According to various aspects, the carrier plate 110 may include a plurality of holding areas

112. The plurality of holding areas 112 may be located on a first side 110-s1, e.g., a top side, of the carrier plate 110. Each of the plurality of holding areas 112 is configured to hold one coupon of the plurality of coupons 10. Therefore, one coupon of the plurality of coupons 10 may be positioned in one holding area of the plurality of holding areas 112. This may be repeated until all holding areas hold one coupon of the plurality of coupons 10. However, it should be noted, that the mounting system 100 may also be used to hold a single coupon 10. Furthermore, it should be noted, that in some cases, a single coupon may be placed in two or more (adjacent) holding areas 112, e.g., if the single coupon is too big for one holding area. Afterward, all coupons of the plurality of coupons 10 may be tested one by one without the need of being replaced. This may reduce an intervention of an operator during the testing procedure.

In the case that the carrier plate 110 is mounted on a chuck (e.g., a wafer chuck), the carrier plate 110 may have a foot print that corresponds to the chuck such that the carrier plate 110 can be positioned and fixated on the chuck.

According to various aspects, the footprint, e.g., a cross section along a lateral plane of the carrier, of the carrier plate 110 may substantially correspond, e.g., may be substantially equal, to the footprint of a standard sized wafer. For example, the carrier plate 110 may have a footprint corresponding to, e.g., substantially equal to a standard sized-wafer, such as one of the following as an example: a one-inch wafer, a two-inch wafer, a three-inch wafer, a four-inch wafer, a six-inch wafer, an eight-inch wafer, a twelve-inch wafer, or an eighteen-inch wafer. For example, the footprint of the carrier plate 110 may be configured such that the standard sized wafer may be fixated on the carrier plate 110. For example, the footprint of the carrier plate 110 may be up to 20% greater (e.g., up to 15%, e.g., up to 10%, e.g., up to 5%) than the footprint of the standard sized-wafer or of the wafer to be held. For example, the footprint of the carrier plate 110 may be up to 20% smaller (e.g., up to 15%, e.g., up to 10%, e.g., up to 5%) than the footprint of the standard sized-wafer or of the wafer to be held. For example, the carrier plate 110 may have a substantially round, e.g., circular, footprint.

According to various aspects, the carrier plate 110 may include (e.g., may be substantially made out of) a carrier plate material. For example, the carrier plate material may include (e.g., may be substantially made out of) a semiconductor material, and/or glass material, and/or a ceramic material, and/or steel. For example, the semiconductor material may include (e.g., may be): silicon, gallium, nitride, carbon, and/or germanium, as an example. For example, the semiconductor material may be doped. For example, the glass may be a non-crystalline, e.g., an amorphous, solid that exhibits a glass transition when it is heated towards the liquid state. For example, a ceramic may refer to an inorganic, nonmetallic solid, that may be based on an oxide, nitride, boride, and/or carbide, which may be fired at a high temperature (e.g., above 500° C.). The carrier plate material may be heat conducting. For example, the carrier plate material may have a heat conductivity of more than 50 W/(m·K) at 20° C. The carrier plate material may be electrically conducting. For example, the electrically conducting carrier plate material may have an electrical conductivity greater than 10⁶ S/m at 20° C. In another example, the carrier plate material may be an electrical insulator. For example, the electrically insulating carrier plate material may have an electrical conductivity of less than 10⁻⁸ S/m at 20° C.

According to various aspects, the carrier plate may have a plate-thickness measured perpendicular to the first side 110-s1 and/or to a second side 110-s2 (e.g., opposite the first side 110-s1) of the carrier plate 110. The plate-thickness may depend on the use-case of the mounting system. However, it should be noted, that a greater plate-thickness may lead to longer vacuum channels. Longer vacuum channels may lead to a decay of the vacuum (e.g., the gaseous pressure may not be decreased enough to reach a predetermined target pressure), which may result in a reduced suction force in the holding areas 112. Therefore, the plate-thickness may be as low as possible. For example, the plate thickness may be in the range of 0.01 mm up to 100 mm, e.g., be in the range of 0.1 mm up to 10 mm, e.g., be in the range of 0.5 mm up to 5 mm, e.g., be in the range of 0.7 mm up to 3 mm, e.g., be substantially 1 mm.

FIG. 1D illustrates one or more aspects of the carrier plate 110, wherein one or more coupons are positioned in the holding areas 112. Each coupon of the plurality of coupons 10 may be fixated within a respective holding area of the plurality of holding areas 112 using a vacuum.

FIG. 1E illustrates various aspects of the carrier plate and the mounting system 100. The carrier plate 110 is depicted in a cross-sectional view along the dotted-dashed-line E illustrated in FIG. 1D. According to various aspects, the mounting system 100 may include and/or may be connected to a vacuum supply system. For example, the carrier plate 110 may be fluid-conductively connected to a vacuum supply system 150. According to various aspects, the mounting system 100 may be configured to use the vacuum provided by the vacuum supply system 150 to apply a force F, e.g., a suction force, to each coupon of the plurality of coupons that is positioned within a holding of the plurality of holding areas 112. Thereby, each coupon of the plurality of coupons 10 may be fixated within the respective holding area.

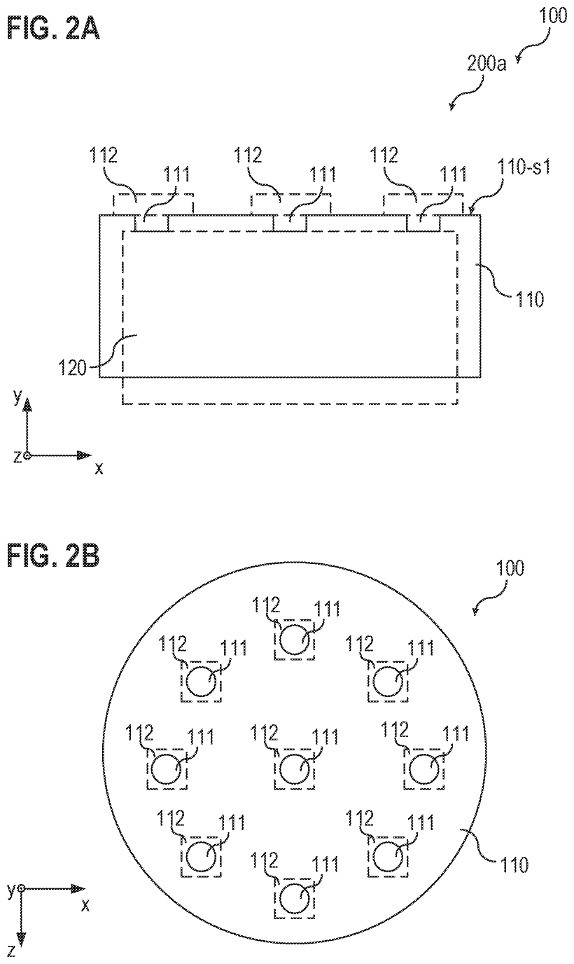

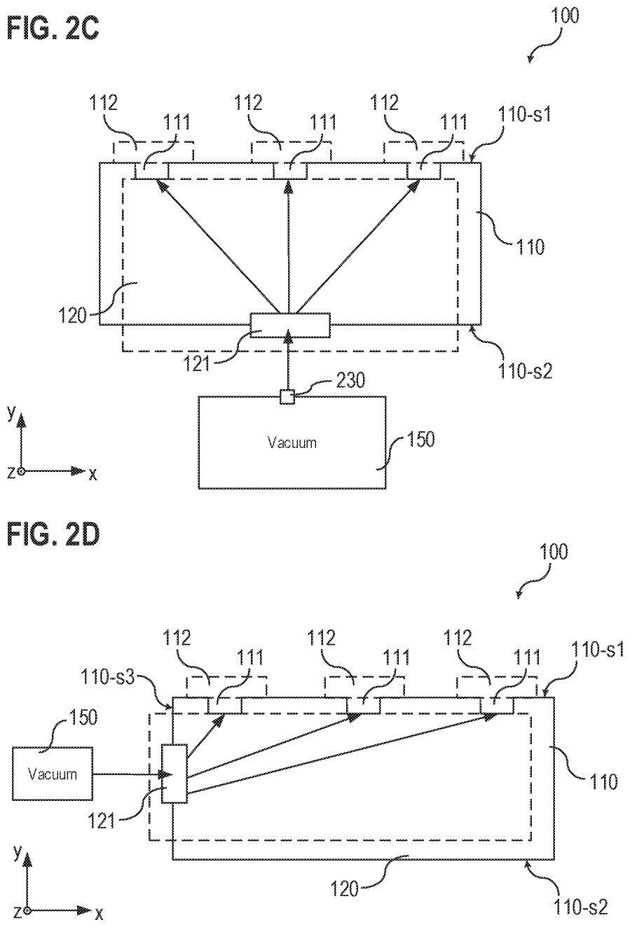

FIG. 2A illustrates schematically a mounting system 100 according to various aspects in a schematic view. The mounting system 100 may include a carrier plate 110 and a vacuum distribution system 120. The mounting system 100 may optionally further include or may be connected to a vacuum supply system 150.

In some aspects, the mounting system 100 may include (e.g., may be configured as or may be) a coupon adapter 200a that is configured to be placed on a chuck plate 410 of a wafer chuck 400. The coupon adapter 200a may include the carrier plate 110 and the vacuum distribution system 120. For example, the carrier plate 110 of the mounting system 100, e.g., of the coupon adapter 200a, may be configured to be laid (e.g., mounted) at least partially on a chuck (e.g., on top of a chuck plate) to provide an adapter function to mount a plurality of coupons 10 on the chuck; wherein, in this case, the mounting system 100 may include the coupon adapter 200a allowing the chuck (which may be a chuck that is not configured to hold a plurality of coupons) to hold a plurality of coupons (i.e., the mounting system is configured as a coupon adapter). In some aspects, the mounting system 100 may include a wafer chuck in addition to the coupon adapter. In some aspects, the mounting system 100 may include (e.g., may be configured as or may be) a coupon chuck 200b. The coupon chuck 200b may include the carrier plate 110 and the vacuum distribution system 120. For example, the carrier plate 110 may act as an exposed chuck plate to mount a plurality of coupons 10 thereon (i.e., the mounting system is formed as a coupon chuck). Both the coupon adapter 200a and the coupon chuck 200b may optionally further include or may be connected to the vacuum supply system 150.

The carrier plate 110 may include a plurality of recess structures 111, which may be disposed in the carrier plate 110. According to various aspects, the mounting system 100 and/or the carrier plate 110 may include a vacuum distribution system 120 to supply a vacuum to the recess structures 111 of the carrier plate 110. For example, the plurality of recess structures 111 may be located on a (e.g., in a) first side 110-s1, e.g., a top side, of the carrier plate 110. For example, the plurality of recess structures 111 may be located on a surface of the carrier plate, on which the plurality of coupons 10 may be positioned on. As described above, the carrier plate 110 may include a plurality of holding areas 112 to receive and hold a respective coupon of the plurality of coupons 10. For example, each recess structure of the plurality of recess structures 111 may define one respective holding area of the plurality of holding areas 112. The plurality of holding areas 112 may be located on the first side 110-s1, e.g., above the respective surface, of the carrier plate 110. For example, each holding area may be located above the corresponding recess structure.

According to various aspects, the vacuum distribution system 120 may be configured to connect the plurality of recess structures 111 to the vacuum supply system 150. For example, the vacuum supply system 150 may be provided by the underlying wafer chuck and/or the vacuum supply system 150 may be independent from the underlying chuck. Due to the vacuum supply system 150, a vacuum, i.e. a lower pressure compared to a pressure in an environmental volume of the carrier plate system or mounting system 100, may be applied to at least one recess structure of the plurality of recess structures 111.

For example, when a coupon of the plurality of coupons 10 is positioned in a holding area of the plurality of holding areas 112, the corresponding recess structure may form a cavity which is bordered by the coupon. The coupon may be regarded as a top surface of the cavity, e.g., a ceiling of the cavity. As described herein, a vacuum may be applied to the plurality of recess structures 111 and, thereby, also to the cavity. In other words, a gaseous pressure within the cavity, i.e., below the coupon, may be lowered due to the vacuum supply system 150 compared to a gaseous pressure present in an environmental volume of the carrier plate 110, e.g., above the coupon. Due to the gaseous pressure difference a force, e.g., a suction force, may be applied to the coupon, that fixates the coupon on the carrier plate 110.

According to various aspects, the vacuum distribution system 120 may be implemented by one or more components of the mounting system 100. Each of the one or more components may be included within the carrier plate, partially within and partially outside of the carrier plate or completely outside of the carrier plate. Therefore, In the figures, the vacuum distribution system 120 is indicated by the dashed line.

In some aspects, one or more elements of the vacuum distribution system 120 may be completely disposed within the carrier plate 110. In some aspects, the vacuum distribution system 120 may include a vacuum channel that may be disposed within the carrier plate 110. The vacuum channel may include (e.g., may be implemented as) a hole through the carrier plate 110, e.g., if the carrier plate 110 is monolithic. The vacuum channel may include (e.g., may be implemented as) a tube. For example, the tube may be disposed within the hole. For example, the carrier plate may be hollow and the tube may penetrate the hollow carrier plate. In some aspects, the vacuum distribution system 120 may include a valve that may be disposed within the carrier plate 110. In some aspects, the vacuum distribution system 120 may include a vacuum connection terminal that may be disposed within the carrier plate 110. For example, the vacuum connection terminal may include a hole. The hole may be an input opening to a vacuum channel. In some aspects, the vacuum connection terminal may include a connector that may be integrated in the carrier plate 110.

In some aspects, one or more elements of the vacuum distribution system 120 may be disposed partially within and disposed partially outside of the carrier plate 110. In some aspects, the vacuum distribution system 120 may include a vacuum channel that may be disposed partially within and disposed partially outside of the carrier plate 110. The vacuum channel may include a tube that may enter the carrier plate 110 via a hole in a surface of the carrier plate. The tube may proceed within the carrier plate 110 in another vacuum channel. For example, if the carrier plate is monolithic, the tube (i.e., as a first vacuum channel) may proceed in a hole through (i.e., as a second vacuum channel) the carrier plate 110. In some aspects, the vacuum distribution system 120 may include a valve that may be disposed partially within and disposed partially outside of the carrier plate 110. In some aspects, the vacuum distribution system 120 may include a vacuum connection terminal that may be disposed partially within and partially outside of the carrier plate 110. For example, the vacuum connection terminal may include a connector that may be integrated in the carrier plate 110 and may have a section that is protruding from a surface of the carrier plate 110.

In some aspects, one or more elements of the vacuum distribution system 120 may be disposed completely outside of the carrier plate 110. In some aspects, the vacuum distribution system 120 may include a vacuum channel that may be disposed completely outside of the carrier plate 110. The vacuum channel may include a tube that may be connected to a second vacuum channel disposed within or at least partially within the carrier plate 110. For example, the tube may connect the second vacuum channel to a third vacuum channel, that may be disposed within or at least partially within the carrier plate 110. For example, the tube may connect the second vacuum channel to a vacuum connection terminal, to a junction or to a valve. In some aspects, the vacuum distribution system 120 may include a valve that may be disposed completely outside of the carrier plate 110. In some aspects, the vacuum distribution system 120 may include a vacuum connection terminal that may be disposed completely outside of the carrier plate 110. For example, the vacuum connection terminal may include a connector that may be connected external of the carrier plate to the vacuum supply system 150. For example, the connector may be connected to a vacuum channel that is disposed completely or at least partially outside of the carrier plate 110.

FIG. 2B illustrates schematically a mounting system 100 according to various aspects in a top view. The mounting system 100 may include a plurality of recess structures 111, each defining a holding area out of a plurality of holding areas 112. According to various aspects, two holding areas may be spaced apart from each other. For example, the two holding areas may not overlap each other. Furthermore, since the plurality of holding areas 112 may be located on (e.g., above) the first side 110-s1 of the carrier plate 110, and the recess structures of the plurality of recess structures 111 may be located on (e.g., within) the first side 110-s1 of the carrier plate 110, two recess structures of the plurality of recess structures 111 may not be connected to each other on the first surface or the first side 110-s1 of the carrier plate 110. For example, a first recess structure and a second recess structure of the plurality of recess structures 111 may not be fluid-conductively connected to each other on the first side 110-s1 of the carrier plate 110. For example, a gas flow (e.g., that may provide a vacuum) from the first recess structure to the second recess structure of the plurality of recess structures 111 on the first side 110-s1 may be inhibited, since the first recess structure and the second recess structure are not fluid-conductively connected to each other on the first side 110-s1.

FIG. 2C illustrates a mounting system 100 according to various aspects in a schematically cross-sectional view, including the vacuum distribution system 120. According to various aspects, the mounting system 100 may include or may be connected to the vacuum supply system 150. For example, the vacuum distribution system 120 may be configured to connect the plurality of recess structures 111 to the vacuum supply system 150. According to various aspects, the vacuum supply system 150 may be any system that is configured to provide a vacuum. For example, the vacuum supply system may include one or more pumps, e.g., vacuum pumps. For example, one or more vacuum traces 413 of a wafer chuck 400 may be part of or may act as the vacuum supply system 150.

According to various aspects, the mounting system 100 may be directly or indirectly fluid-conductively connected to the vacuum supply system 150. According to various aspects, the vacuum distribution system 120 may include a vacuum connection terminal 121 to connect the mounting system 100, e.g., the vacuum distribution system 120, to the vacuum supply system 150. For example, the vacuum connection terminal 121 may be configured to be fluid-conductively connected to the vacuum supply system 150. For example, the vacuum connection terminal 121 may include an opening, e.g., an input opening of one or more vacuum channels of the vacuum distribution system 120. For example, the vacuum connection terminal 121 may be fluid-conductively connected to the vacuum supply system 150, e.g., to the opening of the vacuum connection terminal 121. The vacuum supply system 150 may include a valve 230 that may control a volume flow rate to the vacuum connection terminal 121.

For example, the vacuum terminal or vacuum connection terminal 121, e.g., the opening, may be located on a second surface of the carrier plate 110. For example, the mounting system 100 according to various aspects may be connected to the vacuum supply system 150 of a chuck, e.g., a wafer chuck 400. For example, the vacuum terminal or vacuum connection terminal 121 may be located on the second surface of the carrier plate, such that, the vacuum terminal or vacuum connection terminal 121 fits to at least one groove of a wafer chuck plate 410 of a wafer chuck 400. Thereby, the wafer chuck 400 may act as the vacuum supply system 150 for the mounting system 100, when the carrier plate 110 is placed on the wafer chuck plate 410.

For example, the vacuum terminal or vacuum connection terminal 121 may be connected to a vacuum line that connects the mounting system 100 to the vacuum supply system 150.

FIG. 2D illustrates a mounting system 100 according to various aspects in a schematically cross-sectional view, including the vacuum distribution system 120. According to various aspects, the vacuum distribution system 120 may include a vacuum connection terminal 121. The vacuum connection terminal 121 may be located on the carrier plate 110, e.g., on any side of the carrier plate 110. For example, the connection terminal or vacuum connection terminal 121 may be located on a third side 110-s3, e.g., a lateral side, as shown in FIG. 2D. For example, the connection terminal or vacuum connection terminal 121 may be located on the first side 110-s1 (not shown). For example, the connection terminal or vacuum connection terminal 121 may be located on a second side 110-s2, e.g., a bottom side, as shown in FIG. 2C.

According to various aspects, the vacuum distribution system may include one or more (i.e., more than one) vacuum connection terminal 121. For example, a first of the more than one vacuum connection terminals 121 may be located on one side of the carrier plate 110. A second of the more than one vacuum connection terminals 121 may be located on the same side or on a second side 110-s2 of the carrier plate 110.

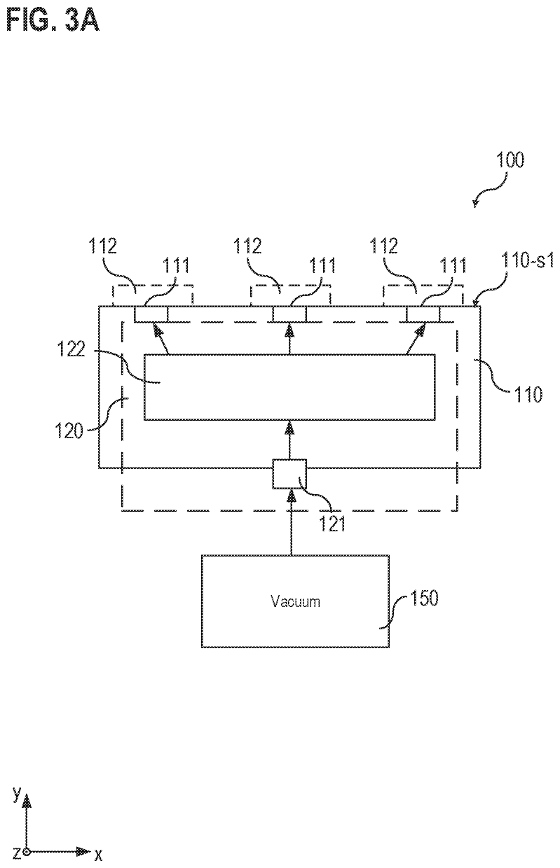

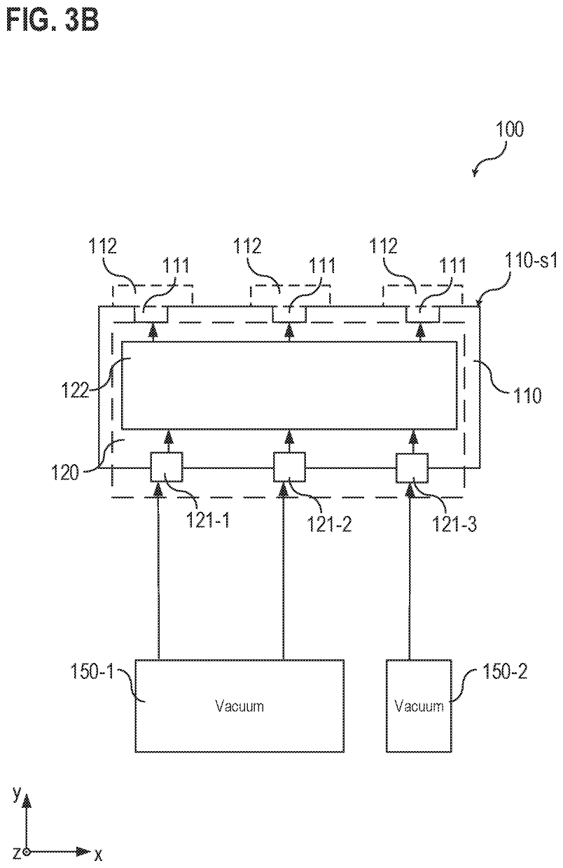

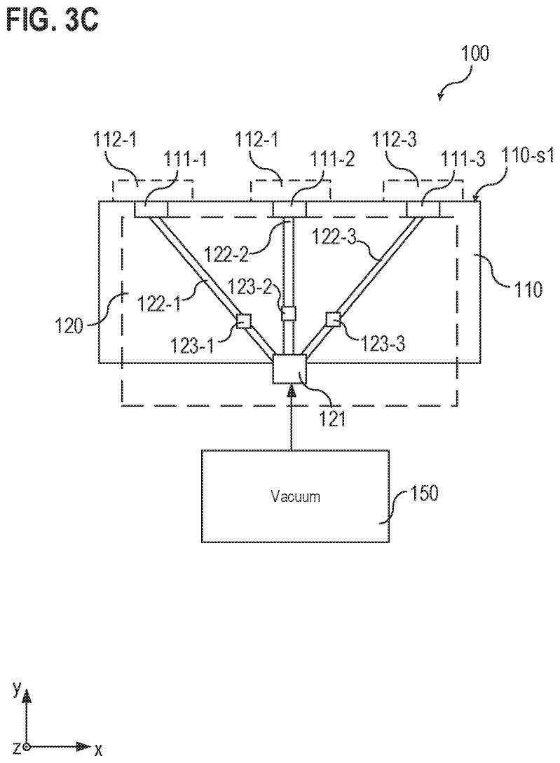

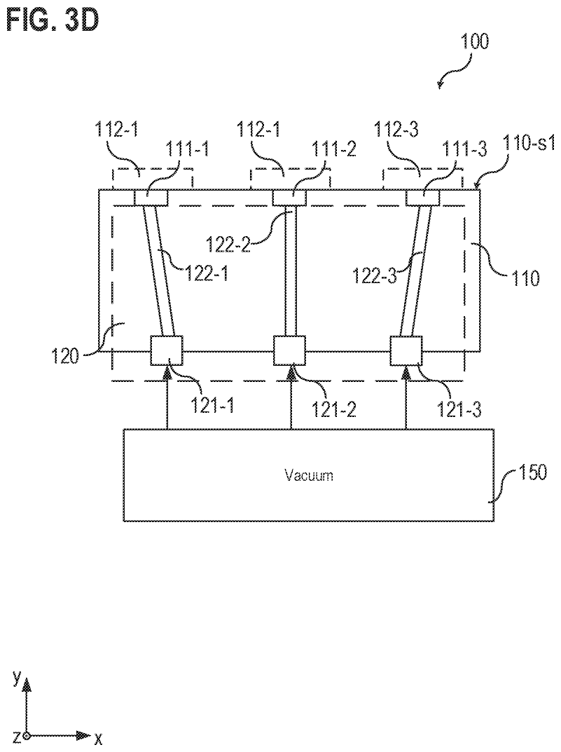

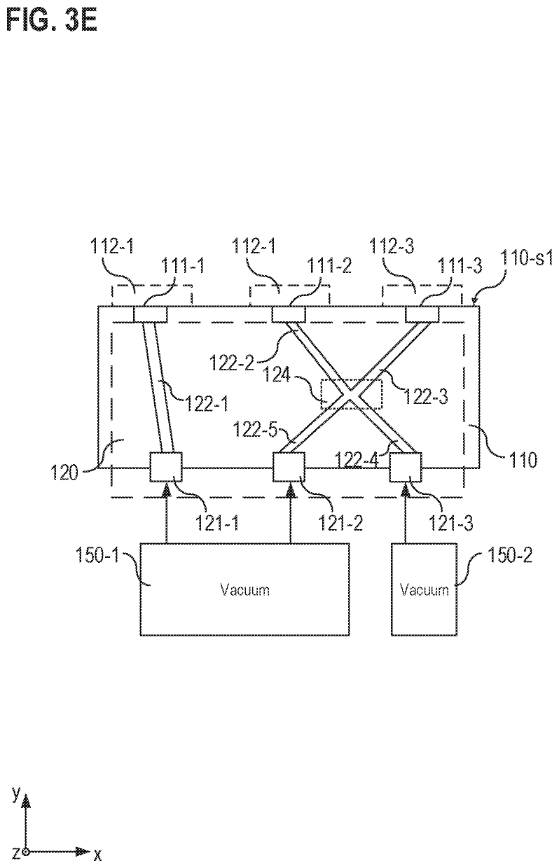

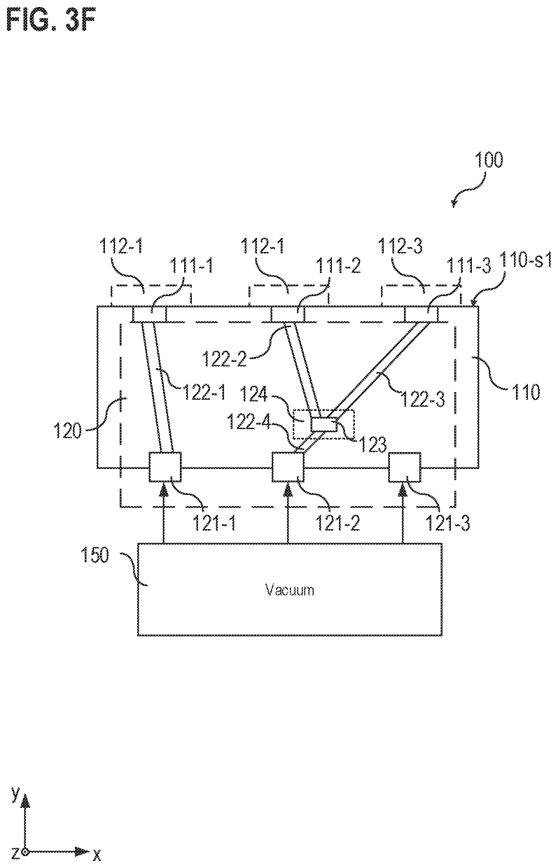

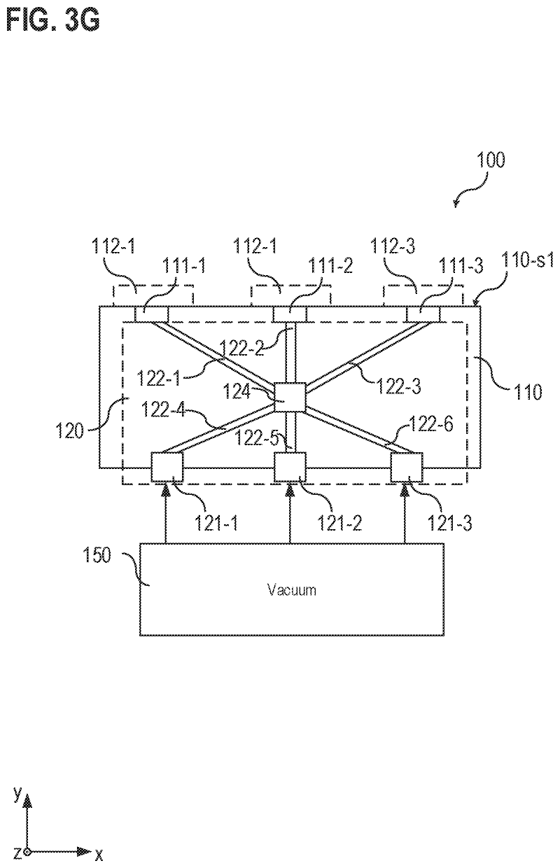

FIG. 3A illustrates a mounting system 100 according to various aspects in a schematically cross-sectional view, including the vacuum distribution system 120 that is connected to the vacuum supply system 150 via a vacuum connection terminal 121. The vacuum connection terminal 121 may be fluid-conductively connected to the vacuum supply system 150 via a vacuum line 152. For example, the vacuum supply system 150 may optionally include a valve 230 to control a volume flow rate through the vacuum line 152.

According to various aspects, the vacuum connection terminal 121 may be fluid-conductively connected to the plurality of recess structures 111, to implement a fluid flow from the at least one recess structure to the vacuum supply system 150. Thereby, the plurality of recess structures 111 may be supplied (e.g., provided) with a vacuum, i.e., a gaseous pressure within the in the plurality of recess structures 111 may be decreased to implement a vacuum. According to various aspects, the vacuum distribution system 120 may include a one or more vacuum channels 122 to provide the fluid-conductive connection from the vacuum connection terminal 121 to the plurality of recess structures 111. The one or more vacuum channels 122 may be arranged in various configurations, and, therefore, the one or more vacuum channels 122 are schematically illustrated by the box, shown in the figures.

According to various aspects, each of the one or more vacuum channels 122 may provide a fluid-conductive connection from one recess structure of the plurality of recess structures 111 to the vacuum connection terminal 121. The one or more vacuum channels 122 may extend from a respective recess structure of the plurality of recess structures 111 to the vacuum connection terminal 121. For example, one of the one or more vacuum channels 122 may include (e.g., may be) a hole (e.g., a bore, a well) through the carrier plate 110. The hole may start at one recess structure of the plurality of recess structures 111, and may end at the vacuum connection terminal 121, e.g., at the opening of the vacuum connection terminal 121. For example, one of the one or more vacuum channels 122 may include (e.g., may be) a line. For example, the line may be inserted (e.g., partially inserted) into the carrier plate 110, e.g., into the hole through the carrier plate 110. For example, the line may be connected to the hole through the carrier plate 110.

FIG. 3B illustrates a mounting system 100 according to various aspects in a schematic cross-sectional view. According to various aspects, the vacuum distribution system 120 may include more than one vacuum connection terminals 121 and one or more vacuum channels 122. Each recess structure of the plurality of recess structures 111 may be fluid-conductively connected to at least one of the more than one vacuum connection terminals 121.

According to various aspects, the mounting system 100 may be fluid-conductively connected to one or more than one vacuum supply systems, e.g., via the more than one vacuum connection terminals 121. For example, the vacuum supply system 150 may be implemented by more than one vacuum supply systems (e.g., a first and a second vacuum supply system, as an example). For example, a first vacuum connection terminal 121-1 of the more than one vacuum connection terminals 121 and a second vacuum connection terminal 121-2 of the more than one vacuum connection terminals 121 may be connected to a first vacuum supply system 150-1. For example, a third vacuum connection terminal 121-3 of the more than one vacuum connection terminals 121 may be connected to a second vacuum supply system 150-2. In one example, this may allow use of different vacuum systems, e.g., to implement a redundancy.

According to various aspects, the fluid-conductive connection between the plurality of recess structures 111 and the more than one vacuum connection terminals 121 may be provided by one or more vacuum channels 122.

As stated before, the one or more vacuum channels 122 may be arranged in various configurations. Some exemplary configurations of the various configurations of the one or more vacuum channels 122 will be explained hereinafter.

Furthermore, according to various aspects, the vacuum distribution system 120 may optionally include one or more valves 123, to control a volume flow rate through the one or more vacuum channels 122. Each valve of the one or more valves may be connected to and/or may be integrated into one or more (e.g., all) of the one or more connection vacuum channels 122.

FIG. 3C illustrates a mounting system 100 according to various aspects in a schematic cross-sectional view. The vacuum distribution system 120 of the mounting system 100 may include one or more vacuum channels 122 arranged in a first exemplary configuration.

In the first exemplary configuration, the vacuum distribution system 120 may include a first vacuum channel 122-1, a second vacuum channel 122-2, and a third vacuum channel 122-3 of the one or more vacuum channels 122. For example, the first vacuum channel 122-1 may provide a fluid-conductive connection between a first recess structure 111-1 of the plurality of recess structures 111 and the vacuum connection terminal 121. For example, the second vacuum channel 122-2 may provide a fluid-conductive connection between a second recess structure 111-2 of the plurality of recess structures 111 and the vacuum connection terminal 121. For example, the third vacuum channel 122-3 may provide a fluid-conductive connection between a third recess structure 111-3 of the plurality of recess structures 111 and the vacuum connection terminal 121.

Furthermore, the vacuum distribution system 120 may include one or more valves 123 to control a volume flow rate through the vacuum distribution system 120, e.g., through the one or more vacuum channels 122. For example, a first valve 123-1 of the one or more valves 123 may be integrated in and/or connected to the first vacuum channel 122-1. The first valve 123-1 may be configured to control (e.g., decrease or increase) a first volume flow rate of a fluid flowing through the first vacuum channel 122-1. For example, a second valve 123-2 of the one or more valves 123 may be integrated in and/or connected to the second vacuum channel 122-2. The second valve 123-2 may be configured to control (e.g., decrease or increase) a second volume flow rate of the fluid flowing through the second vacuum channel 122-2.

For example, the first volume flow rate and the second volume flow rate may differ from each other. For example, the first volume flow rate may be lesser than the second volume flow rate. For example, the first volume flow rate may be zero, while the second volume flow rate is greater than zero, or vice versa. This may allow selectively deactivating (or to selectively deactivate) a vacuum supply for a predefined recess structure of the plurality of recess structures by reducing the corresponding volume flow rate to zero, e.g., by closing the corresponding valve.

For example, a third valve 123-3 of the one or more valves 123 may be integrated in and/or connected to the third vacuum channel 122-3. The third valve 123-3 may be configured to control (e.g., decrease or increase) a third volume flow rate of the fluid flowing through the third vacuum channel 122-3.

FIG. 3D illustrates a mounting system 100 according to various aspects in a schematic cross-sectional view. The vacuum distribution system 120 of the mounting system 100 may include one or more vacuum channels 122 arranged in a second exemplary configuration. The vacuum distribution system may include more than one vacuum connection terminals 121. In contrast to the first exemplary configuration shown in FIG. 3C, each vacuum connection terminal of the multiple vacuum connection terminals 121 may correspond to one recess structure of the plurality of recess structures 111. This may allow for controlling the vacuum supply individually for each recess structure of the plurality of recess structures 111, e.g., a gaseous pressure within each recess structure of the plurality of recess structures 111 may be controlled (e.g., decreased and/or increased (e.g., to a predetermined vacuum associated gas pressure)) individually.

For example, in the second exemplary configuration, the vacuum distribution system 120 may include a first vacuum channel 122-1, a second vacuum channel 122-2, and a third vacuum channel 122-3 of the one or more vacuum channels 122. Furthermore, the vacuum distribution system 120 may include a first vacuum connection terminal 121-1, a second vacuum connection terminal 121-2, and a third vacuum connection terminal 121-3 of the one or more vacuum connection terminals 121. For example, the first vacuum channel 122-1 may provide a fluid-conductive connection between a first recess structure 111-1 of the plurality of recess structures 111 and the first vacuum connection terminal 121-1. For example, the second vacuum channel 122-2 may provide a fluid-conductive connection between a second recess structure 111-2 of the plurality of recess structures 111 and the second vacuum connection terminal 121-2. For example, the third vacuum channel 122-3 may provide a fluid-conductive connection between a third recess structure 111-3 of the plurality of recess structures 111 and the third vacuum connection terminal 121-3.

This configuration may allow selectively disconnecting (or to disconnect selectively) one or more vacuum connection terminals of the one or more vacuum connection terminals from the vacuum supply system 150. Thereby, no vacuum is applied to the corresponding recess structures of the plurality of recess structures 111. This may allow selectively deactivating (or to deactivate selectively) one or more recess structures of the plurality of recess structures 111. For example, if a number of holding areas of the mounting system 100 is greater than a number of coupons, not all holding areas may hold a coupon. Consequently, some of the holding areas may be empty. For example, the coupons may be arranged such that, the empty holding areas may be deactivated, e.g., by disconnecting them from a vacuum supply system 150.

FIG. 3E illustrates a mounting system 100 according to various aspects in a schematic cross-sectional view. The vacuum distribution system 120 of the mounting system 100 may include one or more vacuum channels 122 arranged in a third exemplary configuration. For example, the vacuum distribution system 120 may include a first vacuum channel 122-1 of the one or more vacuum channels 122. The first vacuum channel 122-1 may fluid-conductively connect a first recess structure 111-1 of the plurality of recess structures 111 and the first vacuum connection terminal 121-1 to each other. For example, the first vacuum connection terminal 121-1 may be connected to a vacuum supply system 150 (or a vacuum supply).

According to various aspects, multiple vacuum channels of the one or more vacuum channels 122 may be connected to each other by a junction 124 that is highlighted by a dotted line. For example, a junction 124 may be formed by a crossing, e.g., a fluid-conductive crossing, of two or more vacuum channels. For example, the junction 124 may include (e.g., may be formed by) a cavity within the carrier plate 110. For example, a junction 124 may be formed by (e.g., may include) a valve and/or a switch. The valve may allow control of a vacuum supply. The switch may allow opening and/or closing (or to open and/or close) paths through the junction 124, thereby implementing a switch mechanism between the paths through the junction 124.

The vacuum distribution system 120 may include a second vacuum channel 122-2 that fluid-conductively connects a second recess structure 111-2 to the junction 124. The vacuum distribution system 120 may include a third vacuum channel 122-3 that fluid-conductively connects a third recess structure 111-2 to the junction 124. Furthermore, the vacuum distribution system 120 may include a fourth vacuum channel 122-4 that fluid-conductively connects the junction 124 to the third vacuum connection terminal 121-3. The vacuum distribution system 120 may include a fifth vacuum channel 122-5 that fluid-conductively connects the junction 124 to the second vacuum connection terminal 121-2.

Thereby, each of the second recess structure 111-2 and the third recess structure, 111-3 is connected to the second vacuum connection terminal 121-2 and to the third vacuum connection terminal 121-3, respectively. This may allow supply to both, the second recess structure 111-2 and the third recess structure 111-3, with a vacuum from the same vacuum connection terminal 121, i.e. from the second vacuum connection terminal 121-2 and/or from the third vacuum connection terminal 121-3. Thereby, different vacuum supply systems may be used. For example, the second vacuum connection terminal 121-2 may be connected to the first vacuum supply system 150-1, and the first vacuum connection terminal 121-1, and the third vacuum connection terminal 121-3 may be connected to the second vacuum supply system 150-2.

As explained above, if the number of the plurality of holding areas 112 exceeds the number of the plurality of coupons, not all holding areas may be occupied. In such a case, the coupons may be arranged such that a first holding area 112-1 that corresponds to the first recess structure 111-1 may be empty and does not hold a (or any) coupon. In contrast, the second holding area 112-2 and third holding area 112-3 may not be empty, but instead hold a coupon. In this case, no vacuum is needed to be applied to the first recess structure 111-1 and only the second vacuum supply system 150-2 may be used to fixate the coupon within the second holding area 112-2 and third holding area 112-3, respectively.

FIG. 3F illustrates a mounting system 100 according to various aspects in a schematic cross-sectional view. The vacuum distribution system 120 of the mounting system 100 may include one or more vacuum channels 122 arranged in a fourth exemplary configuration. For example, multiple vacuum channels of the one or more vacuum channels 122 may be connected to each other via a junction 124.

For example, a second recess structure 111-2 of the plurality of recess structures 111 may be connected to a junction 124 via a second vacuum channel 122-2 of the one or more vacuum channels 122. A third recess structure 111-3 of the plurality of recess structures 111 may be connected to the junction 124 via a third vacuum channel 122-3 of the one or more vacuum channels 122. Furthermore, the junction 124 may be connected to the second vacuum connection terminal 121-2 via a fourth vacuum channel 122-4 of the one or more vacuum channels 122.

In another example (not shown), the junction 124 may be connected to only one recess structure of the plurality of recess structures 111 and to at least two vacuum connection terminals of the plurality of vacuum connection terminals 121. The junction may allow changing (or to change) between different vacuum supply systems, each being connected to a single one of the at least two vacuum connection terminals.

FIG. 3G illustrates a mounting system 100 according to various aspects in a schematic cross-sectional view. The vacuum distribution system 120 of the mounting system 100 may include one or more vacuum channels 122 arranged in a fifth exemplary configuration. For example, each recess structure of the plurality of recess structures 111 may be connected to a single junction or one junction 124. Furthermore, the junction 124 may be connected to each vacuum connection terminal of the more than one vacuum connection terminals 121. For example, the junction 124 may be formed (e.g., may include) a cavity within the carrier plate 110. In one example, this may reduce a weight of the carrier plate and/or may provide space for other elements of the mounting system 100 that may be located inside the carrier plate, like a temperature control system as an example.

It should be noted, that the showed exemplary configurations showed one junction 124 to ease the understanding. However, it should be noted that the vacuum distribution system 120 may include more than one junction 124.

According to various aspects, the vacuum supply to the holding areas of the plurality of holding areas 112 may be controlled. For example, the vacuum supply may be increased (e.g., activated), i.e., a gaseous pressure may be decreased (e.g., within a respective recess structure) and, therefore, a force (e.g., a suction force) that may be applied to a coupon may be increased. For example, the vacuum supply may be decreased (e.g., activated), i.e., a gaseous pressure may be increased (e.g., within a respective recess structure) and, therefore, a force (e.g., a suction force) that may be applied to a coupon may be decreased. As stated before, this may be performed for example using valves, switches and/or by providing the corresponding vacuum supply terminals with a vacuum. According to various aspects, the vacuum supply to the plurality of holding areas may be also controlled by covers that may be configured to cover (e.g., to seal) the empty holding areas.

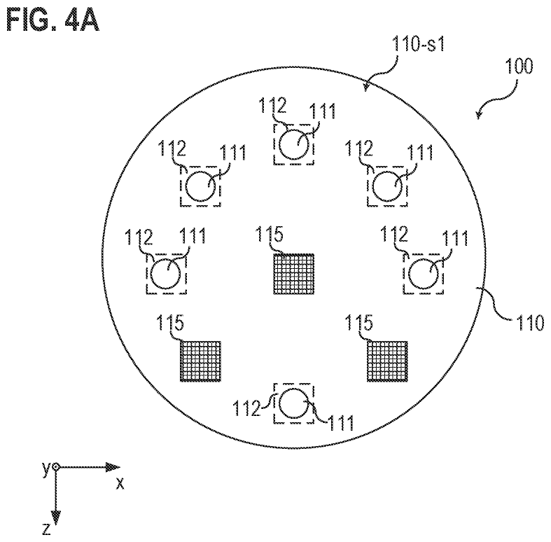

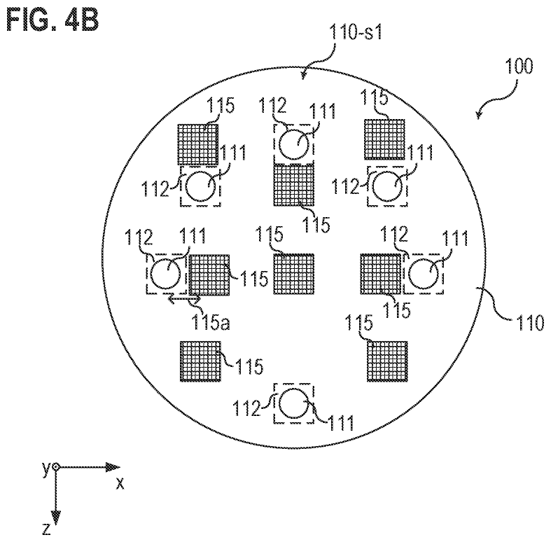

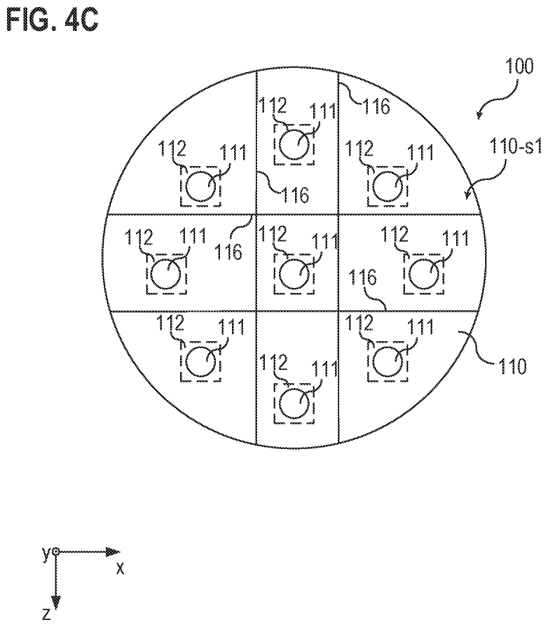

FIG. 4A and FIG. 4B show various aspects of a mounting system 100 in a respective schematic top view. According to various aspects, the mounting system 100 may include a holding area cover 115 to seal an empty holding area of the plurality of holding areas 112. For example, the holding area cover 115 may have geometric dimensions that fit to an empty holding area 112 to cover (e.g., to seal) it. For example, the holding area cover 115 may have an area (e.g., a length and a width) that is large enough to substantially cover the (empty) holding area. For example, the holding area cover 115 may be a dummy coupon, e.g., a coupon without a DUT, that may be laid onto the (empty) holding area. For example, the holding area cover 115 may be attached to the carrier plate 110, whereby the holding area cover 115 may be movable with respect to the carrier plate 110. For example, the holding area cover 115 may be attached to a hinge allowing the holding area cover 115 to be moved to and/or away from the holding area 112. For example, the holding area cover 115 may be configured to be slidable to be moved to the holding area 112, which is indicated in FIG. 4B by the arrow 115a.

According to various aspects, it may be beneficial to position a coupon on a holding area with respect to another coupon. This may ease a testing procedure. According to various aspects, the mounting system 100 may further include an alignment pattern 116 to ease an alignment of coupons that are laid onto the carrier plate 110. For example, the alignment pattern 116 may be formed by multiple dots and/or multiple lines which are disposed on the first side 110-s1 of the carrier plate 110. For example, the alignment pattern 116, e.g., the multiple dots and/or the multiple lines forming the alignment pattern, may be printed, and/or engraved, and/or projected (e.g., via a pattern-projection-device) onto the first side 110-s1 of the carrier plate 110. For example, the alignment pattern 116 may be formed by a laser, e.g., by projection and/or by engraving using the laser. For example, the alignment pattern 116 may include a coordinate system, which may be formed by the multiple dots and/or the multiple lines. For example, the alignment pattern 116 may be formed using chemical procedures (e.g., etching as an example), mechanical procedures (e.g., carving as an example) and/or optical procedures (e.g., laser-based procedures as an example). For example, the alignment pattern 116 may be provided by a separate tool, e.g., a lattice-like tool, having multiple openings that correspond to the positions of the plurality of holding areas. The separate tool may be configured to be laid onto the carrier plate 110 while positioning coupons within the plurality of holding areas. After the plurality of coupons 10 is positioned on the carrier plate 110, the separate tool may be removed from or may stay on the carrier plate 110.

According to various aspects, the alignment pattern 116 may include a unique identifying feature that represents a reference position. For example, the unique identifying feature may be a visible or a non-visible mark, that may be configured to be recognized by a system, e.g., a feature recognition system, that is also configured to recognize an orientation of the plurality of coupons 10.

According to various aspects, the mounting system 100 may further include or may be connected to an alignment-system to align the carrier plate 110 with respect to a position, an orientation, and/or a tilting (e.g., a tilting angle of a surface) of at least one coupon that is held in a holding area of the mounting system 100. For example, the alignment-system may include a rotation-system that may be configured to rotate the carrier plate 110 based on an angular orientation of the at least one coupon that is held in a holding area (e.g., by rotating the mounting system 100 around a center of rotation). For example, the alignment-system may include a moving-system that may be configured to move the carrier plate 110 based on a position of the at least one coupon that is held in a holding area. For example, the alignment-system may include a tilting-system that may be configured to tilt the carrier plate 110 with based on a tilting-angle of the at least one coupon, e.g., an angle (referred to as plate-coupon angle) between a surface of the mounting system and the at least one coupon (e.g., with respect to a slope of a surface of the at least one coupon) that is held in a holding area. The alignment-system may be coupled to a feature recognition system, which is configured to determine the position of the at least one coupon, the orientation of the at least one coupon, the tilting angle of the at least one coupon (e.g., the plate-coupon angle of the at least one coupon). For example, the feature recognition system, e.g., an optical feature recognition system, may be configured to recognize a top left-most reticle on a coupon of the plurality of coupons 10. This may allow adapting (to adapt) a position, a rotation, and/or a tilting angle of the carrier plate 110 to the determined position, orientation, tilting angle (e.g., the plate-coupon angle) of the at least one coupon. For example, the feature recognition system may be configured to perform a feature extraction algorithm (e.g., a convolution-based algorithm or a machine learning-based algorithm (e.g. artificial-intelligence-based), as examples) on the captured image to determine the position, the orientation, the tilting angle (e.g., the plate-coupon angle) of the at least one coupon.

According to various aspects, a recess structure of the plurality of recess structures 111 may include one or more vacuum-distribution-grooves 113. The one or more vacuum-distribution-grooves 113 may be configured to distribute a vacuum within the corresponding recess structure. For example, the vacuum-distribution-grooves 113 may increase an area of the coupon backside that may be subject to a suction effect of the vacuum (e.g., a suction force caused by the vacuum). Thereby, the one or more vacuum-distribution-grooves 113 may improve a suction effect due to the vacuum applied to the corresponding recess structure. The one or more vacuum-distribution-grooves 113 may be formed using chemical procedures (e.g., etching as an example), mechanical procedures (e.g., carving as an example) and/or optical procedures (e.g., laser-based procedures as an example).

According to various aspects each of the one or more vacuum-distribution-grooves 113 may have a groove-width. For example, the groove-width may be in the range of 0.1 mm (or 0.1 mm) up to 3 mm, e.g., in the range of 0.5 mm (or 0.5 mm) up to 2 mm, e.g., may be substantially 1 mm.

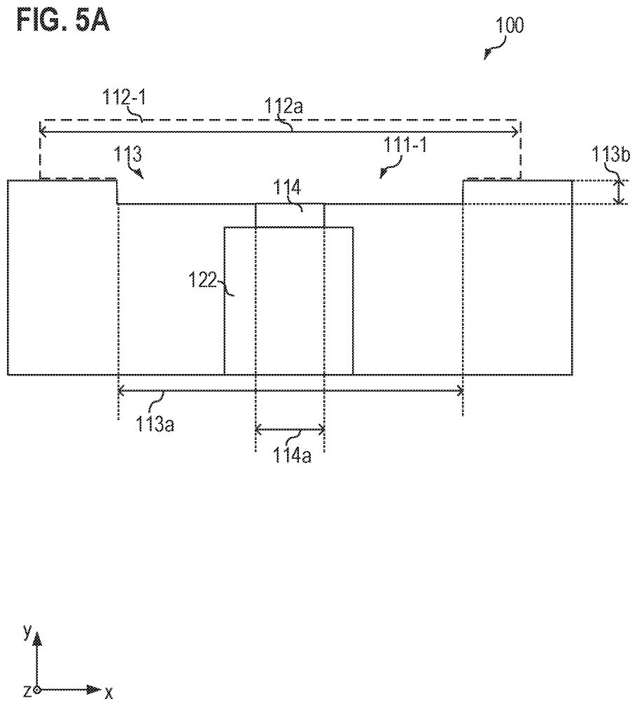

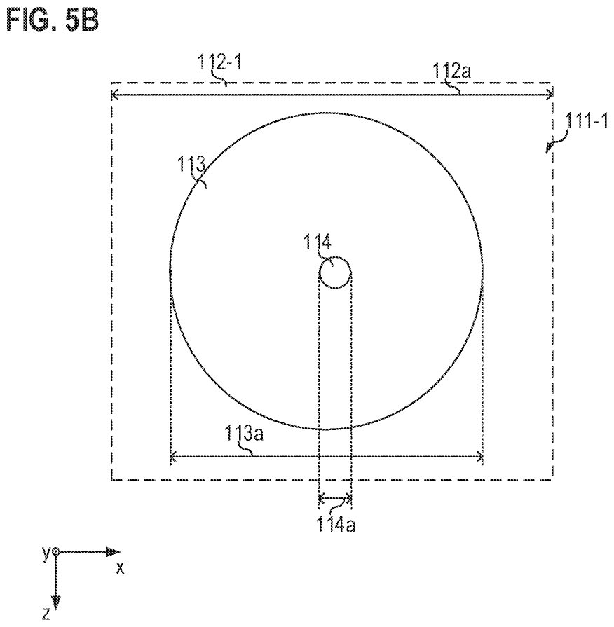

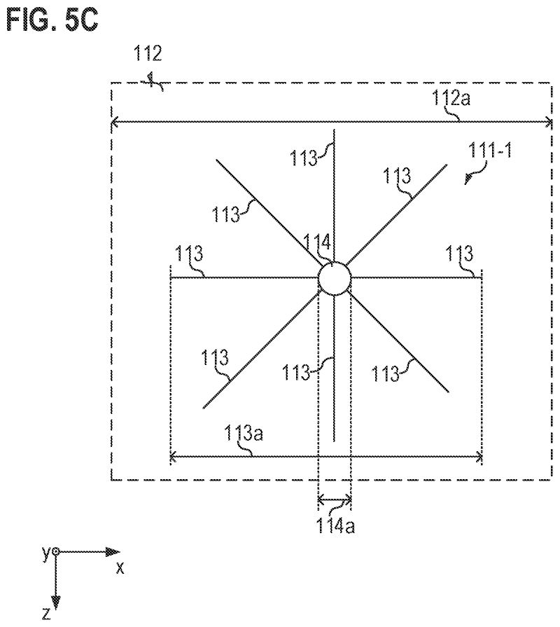

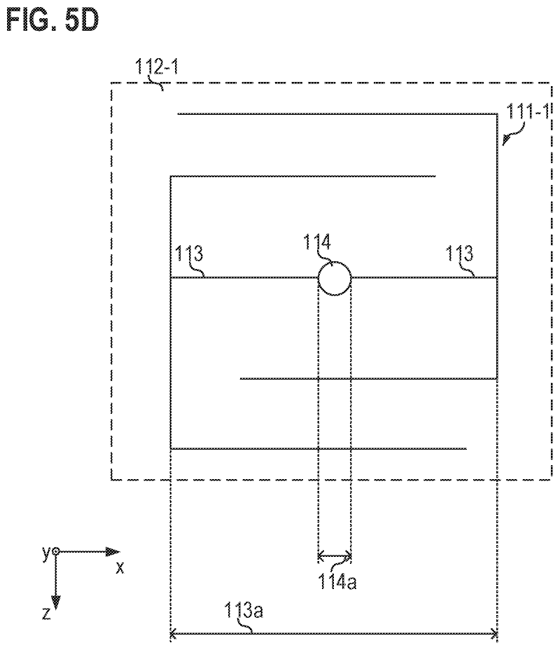

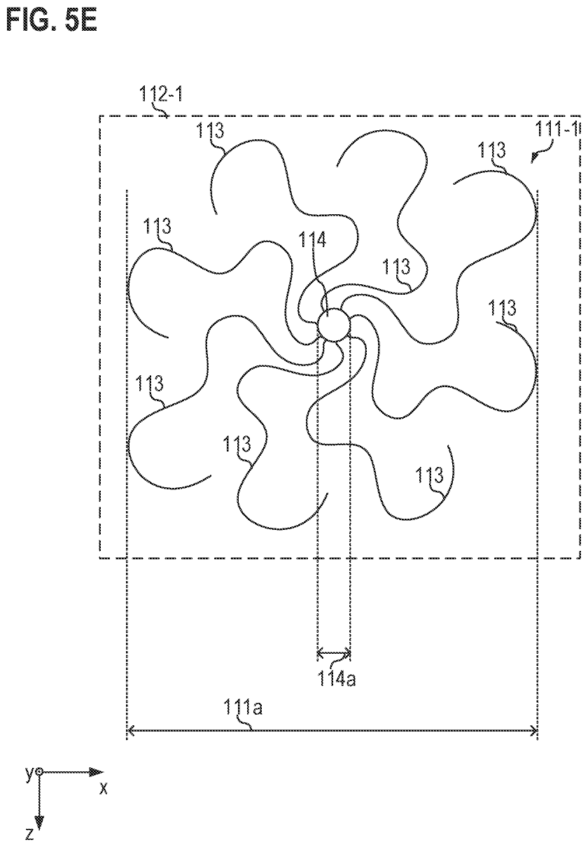

For example, the one or more vacuum-distribution-grooves 113 may be arranged in different shapes. A shape of the one or more vacuum-distribution-grooves 113 may be adapted to a coupon size. FIGS. 5A to 5E show various aspects of the one or more vacuum-distribution-grooves 113.

FIG. 5A illustrates different aspects of a mounting system 100 according to various aspects in a cross-sectional view. Briefly, a single recess structure 111-1 of the plurality of recess structures 111 according to various aspects is illustrated in FIG. 5A. The single recess structure 111-1 may define a corresponding holding area 112-1 of the plurality of holding areas 112. The single recess structure 111-1 may include one or more vacuum-distribution-grooves 113. The one or more vacuum-distribution-grooves 113 may have a lateral extension 113a, which may define a lateral dimension 112a of the holding area 112. For example, the lateral dimension 112a of the holding area may be substantially equal to or greater than the lateral extension 113a of the one or more vacuum-distribution-grooves 113. The lateral extension 113a of the one or more vacuum-distribution-grooves 113 may represent a maximal lateral extension of the one or more vacuum-distribution-grooves 113.

According to various aspects each of the one or more vacuum-distribution-grooves 113 may have a groove-depth 113b. For example, the groove-depth may in the range of 1 μm up to 500 μm, e.g., in the range of 10 μm up to um, e.g., may be substantially 50 μm.

The recess structure 111 may include a vacuum connection hole 114 that connects the recess structure, e.g., the one or more vacuum-distribution-grooves 113, to the vacuum distribution system 120, e.g., to a vacuum distribution channel of the plurality of vacuum distribution channels or vacuum channels 122. For example, the vacuum connection hole 114 may have a lateral extension 114a. The lateral extension 114a of the vacuum connection hole 114 may be lesser than the lateral extension 113a of the one or more vacuum-distribution-grooves 113. For example, each vacuum-distribution-groove of the one or more vacuum-distribution-grooves 113 may have a width (not shown) that may be lesser than the lateral extension 114a of the vacuum connection hole 114. For example, the lateral extension 114a of the vacuum connection hole 114 may be adapted to a lateral extension of a vacuum channel 122, e.g., may be smaller or substantially equal to the lateral extension of a vacuum channel 122. A smaller opening may reduce a volume flow rate through the vacuum connection hole 114.

For example, the lateral extension 114a of the vacuum connection hole 114 may be in the range of 0.2 mm (or 0.2 mm) up to 5 mm, e.g., in the range of 0.5 mm (0.5 mm) up to 3 mm, e.g., in the range of 1 mm up to 2 mm, e.g., may be substantially 1.5 mm (or 1.5 mm).

The one or more vacuum distribution grooves may have different shapes. Therefore, FIGS. 5B to 5E show various aspects of a single recess structure 111-1 of the plurality of recess structures 111, wherein some exemplary shapes of the one or more vacuum-distribution-grooves 113 are shown. It should be noted, that different shapes and types of vacuum distribution grooves may be combined with each other to improve a suction effect.

For example, FIG. 5B illustrates different aspects of a mounting system 100 according to various aspects in a top view. An example of a single recess structure 111-1 is illustrated that includes a single vacuum-distribution-groove 113. For example, the vacuum distribution groove may have a substantially circular form. For example, the vacuum distribution groove may be a circular depression within a surface of the carrier plate 110. For example, FIG. 5C illustrates different aspects of a mounting system 100 according to various aspects in a top view. An example of a single recess structure 111-1 is illustrated that includes more than one vacuum-distribution-grooves 113, wherein each of the one or more vacuum-distribution-grooves 113 may be a straight line that are only connected to each other via the vacuum connection hole 114. For example, FIG. 5D illustrates different aspects of a mounting system 100 according to various aspects in a top view. An example of a single recess structure 111-1 is illustrated that includes more than one vacuum-distribution-grooves 113 wherein each of the one or more vacuum-distribution-grooves 113 may be substantially a line, e.g., a straight line. The more than one vacuum-distribution-grooves 113 may be connected to each other to form a regular or an irregular shape. For example, FIG. 5E illustrates different aspects of a mounting system 100 according to various aspects in a top view. An example of a single recess structure 111-1 is illustrated that includes one or more vacuum-distribution-grooves 113 wherein one of the one or more vacuum-distribution-grooves 113 may have a circular and/or a curved shape.

In another example, the one or more vacuum-distribution-grooves 113 may be formed similar to the vacuum traces 413 of a wafer chuck plate, but smaller.

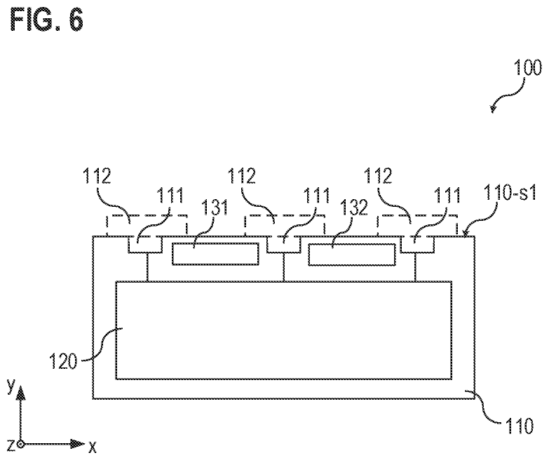

According to various aspects, the mounting system 100 may be configured to control a temperature of the plurality of coupons while the corresponding one or more DUT are tested. FIG. 6 illustrates a mounting system 100 according to various aspects, that includes a temperature control system. The temperature control system may include a heating system 131 to heat and/or a cooling system 132 to cool the carrier plate 110, e.g., the first side 110-s1 of the carrier plate 110. The temperature control system may further include a temperature controller that is configured to control the heating system 131 and/or the cooling system 132.

As described herein, the mounting system 100 is configured in some aspects to allow for processing of a plurality of coupons 10 instead of a single wafer 401. Therefore, the mounting system 100 may include a coupon adapter for an already existing chuck, e.g., for a wafer chuck 400. In one or more other aspects, the mounting system 100 may include a chuck. Both exemplary use-cases will be described in the following.

FIG. 7A illustrates various aspects of the mounting system 100 including a coupon adapter 200a, e.g., a chuck plate adapter for a wafer chuck 400. According to various aspects, the carrier plate 110 may be referred to as an “adapter plate”. The adapter plate may be laid on a wafer chuck plate 410 to provide a mounting system 100. For example, the second side of the carrier plate 110-s2 may be laid on a first surface 410-s1 of the wafer chuck plate 410. For example, the second side 110-s2 of the carrier plate may have a substantially planar surface, such that it may fit on the first surface 410-s1 of the wafer chuck plate 410. For example, the wafer chuck plate 410 may include one or more vacuum traces 413. The one or more vacuum traces 413 may be sealed by the second side 110-s2 of the carrier plate 110.

FIG. 7B illustrates various aspects of the mounting system 100 including a coupon adapter 200a, e.g., a chuck plate adapter for a wafer chuck 400. According to various aspects, the mounting system 100, e.g., the carrier plate 110, may be fixated on the wafer chuck plate 410. The mounting system 100 may be fixated using a vacuum, that is applied to the one or more vacuum traces 413 of the wafer chuck plate 410. For example, the vacuum may generate a force F, e.g., a suction force F, that fixates the carrier plate 110 of the mounting system 100 to the wafer chuck plate 410.

According to various aspects the wafer chuck plate 410 may further include one or more clamps 430 that may be used to hold the mounting system 100 on the wafer chuck plate 410. For example, the one or more clamps 430 may be used to attach the mounting system 100, e.g., the carrier plate 110, to the wafer chuck plate 410. For example, the one or more clamps 430 may be used to fixate the mounting system 100 on the carrier plate instead of or additionally to the one or more vacuum traces 413. For example, the carrier plate 110 may include one or more attachment structures (e.g., a notch, a protrusion etc.) corresponding to the one or more clamps 430 that may be used to attach the carrier plate 110 to the wafer chuck plate 410 using the one or more clamps 430. For example, the one or more clamps 430 may be arranged on the wafer chuck plate 410 such that they inhibit a movement of the mounting system 100 on the chuck. For example, the one or more clamps 430 may be positioned adjacent to the mounting system 100, thereby inhibiting a movement of the mounting system 100 (e.g., inhibiting a slipping of the carrier plate 110 from the wafer chuck plate 410). For example, the one or more clamps 430 may include an adhesive element, e.g., a magnet, an element to provide a tight fit, and/or an element to provide a force fit to fixate the mounting system 100 to the chuck plate 410.

According to various aspects, an adhesive layer, e.g., a grippy layer, e.g., an anti-slide mat, may be positioned between the wafer chuck plate 410 and the mounting system 100 to fixate the mounting system 100 on the wafer chuck plate 410. For example, the adhesive layer may have multiple holes, that correspond to the one or more vacuum connection terminals 121 of the mounting system 100.

According to various aspects, the second side 110-s2 of the carrier plate 110 that is laid on the wafer chuck plate, may be configured to fit to, e.g., to fit in, the one or more vacuum traces 413 of the wafer chuck 400. For example, the carrier plate 110 may include one or more recesses that fit into the one or more vacuum traces 413 of the wafer chuck 400.

FIG. 7C illustrates various aspects of the mounting system 100 including a coupon adapter 200a, e.g., a chuck plate adapter for a wafer chuck 400. According to various aspects, the vacuum distribution system 120 of the mounting system 100 may be fluid-conductively connected to the one or more vacuum traces 413 of the wafer chuck 400. For example, one or more (e.g., all) of the one or more vacuum input terminals (or vacuum connection terminals) 121 may be arranged such that they correspond (e.g., fit) to one or more of the vacuum traces 413 of the wafer chuck 400. For example, one or more (e.g., all) of the one or more vacuum input terminals (or vacuum connection terminals) 121 may be arranged such that they form a fluid-conductive connection to one or more of the vacuum traces 413 of the wafer chuck 400. Thereby, the vacuum, which is provided by the vacuum supply system 150 to the wafer chuck 400, e.g., to the one or more vacuum traces 413, may be passed on to the mounting system 100, e.g., to the vacuum distribution system 120 of the mounting system 100. For example, the wafer chuck 400 (together with the vacuum supply system 150 connected thereto) may be regarded as a vacuum supply system 150 of the mounting system 100.

FIG. 7D illustrates various aspects of the mounting system 100 including a coupon adapter 200a, e.g., a chuck plate adapter for a wafer chuck 400 from a top view. According to various aspects, the vacuum distribution system 120 of the mounting system 100 may be connected to the one or more vacuum traces 413 of the wafer chuck 400. The wafer chuck 400 may be connected to a vacuum supply system 150. As described herein, the plurality of holding areas 112 may be located on the first side 110-s1 of the mounting system 100. Furthermore, one or more holding areas of the plurality of holding areas 112 may be arranged correspondingly to the one or more vacuum traces 413. For example, each of the one or more holding areas 112 may be arranged substantially above one of the one or more vacuum traces 413. This may allow, that a corresponding vacuum channel of the plurality of vacuum channels may be implemented by a substantially straight hole from the first side of the carrier plate 110 to the second side 110-s2 of the carrier plate 110 going through the carrier plate 110. For example, the hole may be substantially perpendicular to the first side 110-s1 and/or to the second side 110-s2 of the carrier plate 110.

For example, the carrier plate 110 may be a substantially unprocessed wafer (e.g., a semiconductor wafer, e.g., a silicon wafer), which may be modified with one or more vacuum channels 122, e.g., holes, to propagate a vacuum from the wafer chuck 400 underneath to each holding area 112. Thereby, each coupon positioned within the holding area may be fixated. Additional vacuum-distribution-grooves 113 that are fluid-conductively connected to the vacuum supply system 150 may be carved in the carrier plate 110 to increase an area of the coupon backside subject to the suction effect of the vacuum.

FIG. 7E illustrates various aspects of the mounting system 100 including a coupon adapter 200a, e.g., a chuck plate adapter for a wafer chuck 400 from a top view. The wafer chuck 400 may be connected to a vacuum supply system 150, which may allow to fixate the mounting system 100 on the wafer chuck plate 410 using the one or more vacuum traces 413. For example, the mounting system 100 may be fixed to the chuck plate 410 by one or more clamps 430 (not shown).

According to various aspects, the mounting system 100 may be connected to the vacuum supply system 150 using a connection that is independent from the wafer chuck 400. For example, the vacuum distribution system 120 of the mounting system 100 may include a vacuum connection terminal 121, which is configured such that it allows for a fluid-conductive connection to the vacuum supply system 150 (or the vacuum supply) independent from the wafer chuck 400. For example, the vacuum terminal or vacuum connection terminal 121 may be arranged on any side of the carrier plate, but the side that is laying on the wafer chuck plate 410. This may allow deactivating (to deactivate) a vacuum supply to the wafer chuck 400. If the vacuum supply of the wafer chuck 400 is deactivated, the mounting system may be fixated using the one or more clamps 430 and/or the adhesive layer (not shown).

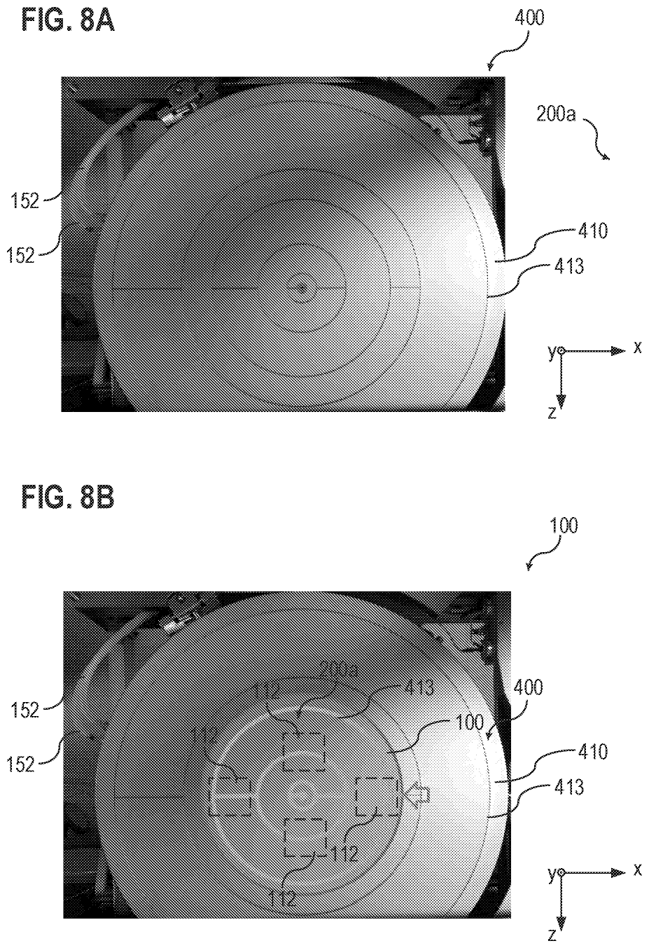

FIG. 8A shows a photography of a wafer chuck 400 including a wafer chuck plate 410 and one or more vacuum traces 413. The wafer chuck 400 may be connected by one or more vacuum lines 152 to a vacuum supply system 150 (not shown).

FIG. 8B shows a photograph of the wafer chuck 400 of FIG. 8A, wherein a mounting system 100 including as a coupon adapter 200a, is illustrated such that the coupon adapter 200a is placed on the wafer chuck plate 410. The vacuum traces of the one or more vacuum traces 413 that are covered by the mounting system 100 are highlighted using thick lines within the mounting system 100. Furthermore, the holding areas of the plurality of holding areas 112 are arranged such that each holding area is located above one of the one or more vacuum traces 413.

The mounting system 100 as explained herein may include a coupon chuck 200b. FIG. 9 illustrates the coupon chuck 200b according to various aspects. For example, the coupon chuck 200b may include the carrier plate 110. The carrier plate 110 of the chuck may be the carrier plate 110 of the mounting system 100. The chuck may include a vacuum distribution system 120, which may be the vacuum distribution system 120 of the mounting system. For example, the coupon chuck 200b may include or may be connected to a vacuum supply system 150 (e.g., of the mounting system 100). For example, the vacuum distribution system 120 may be connected the vacuum supply system 150. For example, the vacuum supply system 150 may be connected to a vacuum connection terminal of the vacuum distribution system, e.g., via a line as an example.

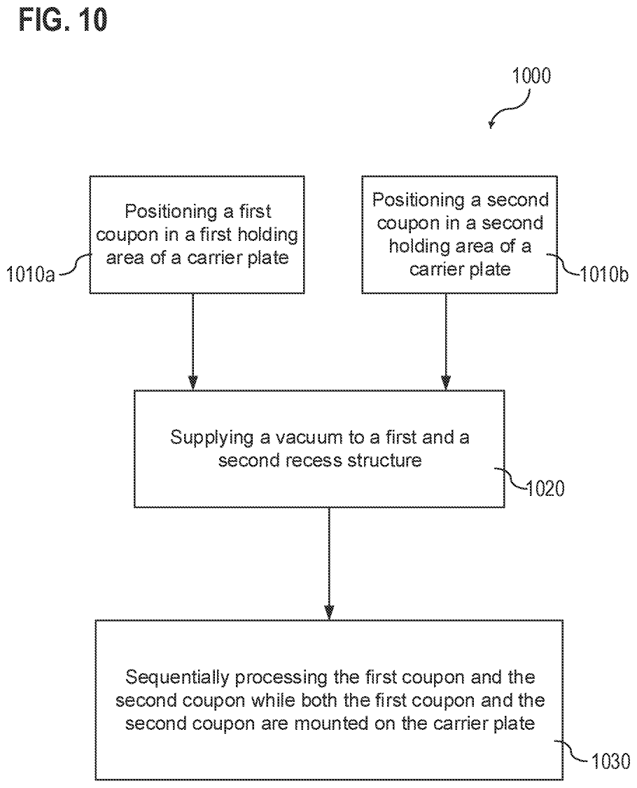

FIG. 10 illustrates schematically a method 1000 according to various aspects to process, e.g., to test, a plurality of coupons 10 using a processing tool, e.g., a prober. The processing tool may include a mounting system 100 according to various aspects. For example, the processing tool may include a chuck. According to various aspects, the mounting system may include the chuck, as explained herein. In some aspects, the chuck may be a coupon chuck 200b. In some other aspects, the chuck may be a wafer chuck 400.

The method 1000 may include positioning a first coupon of the plurality of coupons in a first holding area of a carrier plate 1010a and positioning mounting a second coupon of the plurality of coupons in a second holding area of the carrier plate 1010b. The method may further include, supplying a vacuum 1020 to a first and a second recess structure of a plurality of recess structures in the carrier plate. The first recess structure may define the first holding area and the second recess structure may define the second recess structure. The supplied vacuum may fixate the first coupon covering the first recess structure in the first holding area, and the second coupon covering the second recess structure in the second holding area.

Additionally, the method may optionally further include sequentially processing the first coupon and the second coupon 1030 while both the first coupon and the second coupon are mounted on the carrier plate. For example, between processing (e.g., testing) the first coupon and the second coupon, there may be no need to change the coupons and/or to stop the processing.

The method may further include, deactivating (or deactivate) the vacuum supply to a recess structures out of the plurality of recess structures that is not covered by coupon. The method may further include placing a cover in a third holding area, that does not hold any coupon. Thereby a third recess structure defining the third holding area may be sealed.

In some aspects, the carrier plate, may be an adapter plate of a coupon adapter 200a. In this case, the method may further include mounting the carrier plate on a surface of a wafer chuck 400. Furthermore, the carrier plate may be aligned corresponding to the surface of the wafer chuck 400. For example, the carrier plate may be aligned corresponding a vacuum trace of a chuck plate of the wafer chuck 400.

According to various aspects, the mounting tool or mounting system 100 may be included in a processing tool, e.g., a prober. The processing tool may further include an alignment-system that is configured to align the mounting tool or mounting system 100 with respect to a position, an orientation, and/or a tilting angle (e.g., a tilting angle of a surface of the at least one coupon, and/or the plate-coupon angle) of a coupon to be tested that is held in a holding area of the mounting tool or mounting system 100. Furthermore, the processing tool may include a feature recognition system that may be configured to recognize a feature of the coupon to be tested that is held in a holding area of the mounting tool or mounting system 100. For example, the feature recognition system may be configured to determine an orientation, and/or a position, and/or a tilting angle of the coupon with respect to the mounting tool or mounting system 100 based on the recognized feature. For example, the feature recognition system may be configured to identify the orientation, and/or the position, and/or the tilting angle of the coupon based on a captured image of the coupon positioned on the mounting device. For example, the feature recognition system may be configured to perform a feature extraction algorithm (e.g., a convolution-based algorithm or a machine learning-based algorithm (e.g., artificial-intelligence-based), as examples) on the captured image to determine the orientation, position and/or tilting angle of the coupon to be tested. The determined orientation, and/or position, and/or tilting angle may allow to align the coupon to be tested exactly underneath a needle probe interface of the processing tool. Thereby, the needle probe interface of the processing tool may precisely physically contact the coupon. For example, the needle probe interface (e.g., a needle) may be mechanically fastened within a testing-structure of the processing tool. According to various aspects, the alignment-system may be connected to a controller, which is configured to control the alignment system, e.g., to control one or more components of the alignment system such as a moving-system, a rotation-system, a tilting-system.

According to various aspects, the alignment-system may include a moving-system. The moving system may be configured to move the mounting system 100, during a movement phase, within the processing tool along a horizontal plane (i.e., in an x-y plane) until the coupon to be tested that is held on the mounting system 100 is located exactly underneath the needle probe interface. For example, the moving system may be configured to move the mounting system 100 within the processing tool along a vertical axis (i.e., in a z-direction that may be perpendicular to the x-y-plane). This may allow for lifting up or for lowering down the mounting system 100 until the needle probe interface touches all associated contact pads of the coupon to be tested. Once the electrical connection is established between the processing tool and the coupon held on the mounting system 100, the processing tool may be configured to issue a first signal to a testing device (e.g., a tester), which may be coupled to the processing tool, to start running a test flow on the coupon to be tested. For example, during the test flow, the testing device may contact the coupon to be tested by the needle probe interface that may include a set of needle probes. The needle probe interface may be configured to contact corresponding metal areas (e.g., pads) located on the coupon to be tested to apply voltages to the coupon (e.g., including ground voltage) and/or to transmit test-signals to the coupon that may allow for exchanging information between the testing-device and the coupon.

Once the test-flow has ended, the testing-device may be configured to send a second signal to the processing tool requesting the processing tool to move on from the currently tested coupon to a next testable coupon held on the mounting system 100, or to end the testing, if no next testable coupon held on the mounting system 100 is held. For example, before the next testable coupon held on the mounting system 100 is tested, the processing tool may be configured to move the mounting system 100 along the vertical axis (i.e., along the z-axis). This may allow for implementing a safe distance between the currently tested coupon and the needle probe interface, to enable moving the mounting system 100 freely underneath the needle probe interface without damaging, e.g., scratching, the surface of the currently tested coupon or the needle probe interface. After the safe distance is implemented, the alignment-system may be configured to move the mounting system 100 within the horizontal plane such that the next testable coupon is located exactly underneath the needle probe interface, as described before. Afterwards, the process tool may be further configured to implement a physical connection between the needle probe interface and all associated contact pads of the next testable coupon by his may moving the mounting system 100 along the vertical axis. When the physical contact is established, the first signal may be transmitted to the testing device to start the testing procedure, and when the testing has finished, the second signal may be emitted from the testing device, as described herein. This procedure may be repeated until all testable coupons held on the mounting system 100 are tested using the processing tool.

In some aspects, the alignment system may further or alternatively include a tilting-system to tilt the mounting system with respect to the needle probe interface and/or a rotation-system to rotate the mounting system with respect to the needle probe interface. Thereby, the positioning of each testable coupon may be improved with respect to the needle probe interface.

In some aspects, the processing tool may be configured to exactly move the mounting system 100 along the horizontal plane to have each testable coupon contacted in sequence to the testing device, e.g., via the probe needle interface. Therefore, the processing tool may be configured, in an alignment phase, to determine a respective position (e.g., represented by an x-offset and an y-offset, or corresponding coordinates) as well as a respective orientation (e.g., represented by an angular offset) of each testable coupon. Based on the determined respective positions as well as the respective orientations of all testable coupons positioned on the mounting system, a high precision alignment within the horizontal plane may be performed. The determination of the respective positions as well as the respective orientations of all testable coupons may be performed using the feature recognition system, which may provide knowledge of the distances between the testable coupons held on the mounting system.

In some aspects, the processing tool may be configured to exactly move the mounting system 100 along the vertical plane to have each testable coupon contacted to the testing device, e.g., via the probe needle interface. Therefore, the feature recognition system may be configured to recognize a height (e.g., in the vertical direction) of each testable coupon mounted on the mounting system 100 with respect to an upper surface of a carrier plate of the mounting system. For example, during the alignment phase, the alignment-system may be configured to perform a movement along the vertical direction (ΔZ) to have a corresponding coupon to be tested connected to or disconnected from the needle probe interface. This may allow for testing multiple coupons having different heights using the processing tool.

In some aspects, if a surface of a coupon is oblique or tilted, the feature recognition system may be configured to determine a corresponding tilting angle. Furthermore, the alignment-system, e.g., the tilting-system, may be configured to tilt the mounting system 100, e.g., the carrier plate 110, according to the tilting angle thereby allowing for implementing of a physical connection between the needle probe interface and the coupon to be tested.

According to various aspects, the processing tool may further include a storage device, e.g., memory device, which is configured to store the information determined by the feature recognition system, such as the respective position, the respective orientation, and/or the respective tilting angle of each testable coupon. For example, that information may be stored for each coupon individually. For example, the stored information may be retrieved when the corresponding coupon is to be contacted.

According to various aspects, the processing tool, e.g., the prober, may refer to a robotic machinery configured to ensure a temporary steady contact between a device under test (“DUT”) in a coupon and a testing device (e.g., a tester), such that the DUT may be tested. The processing tool may include a plate (e.g., a chuck) which may be freely moved along the three orthogonal axes (e.g., an x-axis, a y-axis, and a z-axis). The plate may be configured to hold a mounting system (e.g., the carrier plate of a mounting system), on which the coupons (each including one or more DUT) may be positioned on (e.g., evenly spaced). For example, the mounting system may be secured to the plate via a vacuum provided from a vacuum system of the processing tool. A vacuum distribution system of the mounting system may be configured to further distribute the vacuum from a backside of the mounting system (e.g., from grooves carved in a continues pattern on a backside-surface of the carrier plate of the mounting system) to a front side a of the mounting system (e.g., to a front side of the carrier plate of the mounting system).

In the following, various examples are provided that refer to a mounting system according to various aspects, that may include a chuck (e.g., a coupon chuck or a wafer chuck) and/or a coupon adapter (e.g., an adapter for a wafer chuck to hold and/or process multiple coupons at the same time), and to a method to test a plurality of coupons using a processing tool.

Example 1 is a mounting system to process, e.g., test, a plurality of coupons, the mounting system may include: a coupon chuck, the coupon chuck may include: a carrier plate that may include a plurality of recess structures disposed in the carrier plate, wherein each of the plurality of recess structures defines one holding area of a plurality of holding areas on the carrier plate to receive and hold a respective coupon of the plurality of coupons, and a vacuum distribution system to connect the plurality of recess structures to a vacuum supply system.

Example 2 is the mounting system according to example 1, that may further include a vacuum supply system.

Example 3 is the mounting system according to example 1 or 2, wherein the vacuum distribution system may further include one or more vacuum connection terminals to connect the vacuum distribution system to a vacuum supply system (e.g., the vacuum supply system of Example 2). For example, the vacuum supply system and the vacuum distribution system may be connected to each other via a vacuum line.

Example 4 is the chuck according to anyone of examples 1 to 2, wherein the vacuum distribution system may further include one or more vacuum channels that are at least partially in the carrier plate and configured to connect the plurality of recess structures to a vacuum supply system.

Example 5 is the mounting system according to example 4, wherein a first vacuum channel of the one or more vacuum channels and a second vacuum channel of the one or more vacuum channels cross each other thereby forming a fluid-conductive junction.

Example 6 is the mounting system according to example 4 or 5, wherein a first vacuum channel of the one or more vacuum channels may be configured to connect a first recess structure of the plurality of recess structures and a first vacuum connection terminal of the plurality of vacuum connection terminals to each other.

Example 7 is the mounting system according to anyone of examples 4 to 6, wherein a second vacuum channel of the one or more vacuum channels may be configured to connect a second recess structure of the plurality of recess structures and a second vacuum connection terminal of the plurality of vacuum connection terminals to each other.

Example 8 is the mounting system according to example 7, wherein a third vacuum channel of the one or more vacuum channels may be configured to connect a third recess structure of the plurality of recess structures and the second vacuum connection terminal of the plurality of vacuum connection terminals to each other.

Example 9 is the mounting system according to anyone of examples 1 to 8, wherein the vacuum distribution system further may include one or more valves and/or one or more switches to control a vacuum flow through the vacuum distribution system. For example, the valve and/or the switch may be disposed at a vacuum channel of the one or more vacuum channels to control a vacuum flow therethrough.

Example 10 is the mounting system according to anyone of examples 1 to 9, wherein the recess structures of the plurality of recess structures may be located on a first side (e.g., a top side) of the carrier plate. For example, the recess structures of the plurality of recess structures may be located on a first surface at the first side of the carrier plate.

Example 11 is the mounting system according to anyone of examples 1 to 10, which may further include: an alignment pattern (e.g., a coordinate system) to align the respective coupon relative to each other on the carrier plate.

Example 12 is the mounting system according to example 11, which may further include: a pattern-projection-device to project the alignment pattern to a first side of the carrier plate.

Example 13 is the mounting system according to example 11 or 12, wherein the alignment pattern may include a plurality of alignment structures; and wherein one or more of the holding areas are arranged between two neighboring alignment structures of the plurality of alignment structures.

Example 14 is the mounting system according to anyone of examples 1 to 13, which may further include: an alignment-system to align the carrier plate with respect to an angular orientation, and/or a position, and/or a tilting angle of at least one coupon of the plurality of coupons. For example, the alignment-system may include a rotation-system that is configured to rotate, e.g., tilt, the mounting system according to the angular orientation of at least one coupon of the plurality of coupons.

Example 15 is the mounting system according to anyone of examples 1 to 14, wherein a recess structure of the plurality of recess structures (e.g., all of the plurality of recess structures) may include one or more vacuum-distribution-grooves.

Example 16 is the mounting system according to example 15, wherein the one or more vacuum-distribution-grooves are formed in circular shape, in a meander like shape, in an angular shape (e.g., a cornered shape, rectangular shape), in a circular shape or in a mixed shape thereof.

Example 17 is the mounting system according to anyone of examples 1 to 16, wherein a recess structure of the plurality of recess structures (e.g., all of the plurality of recess structures) may include a vacuum connection hole that is configured to connect the at least one recess structure (e.g., the one or more vacuum-distribution-grooves), to the vacuum distribution system (e.g., to one of the one or more vacuum channels).

Example 18 is the mounting system according to example 17, wherein the recess structure may have a total lateral extension measured along the carrier plate that may be greater than a lateral extension of the vacuum connection hole.

Example 19 is the mounting system according to anyone of examples 15 to 18, wherein each of the one or more vacuum-distribution-grooves may have a width that may be less than a lateral extension of the vacuum connection hole.

Example 20 is the mounting system according to anyone of examples 15 to 19, wherein

a first vacuum-distribution-groove of the one or more vacuum-distribution-grooves may be connected to a second of the one or more vacuum-distribution-grooves only via the vacuum connection hole.

Example 21 is the mounting system according to anyone of examples 15 to 20, wherein the recess structure may include one or more vacuum-distribution-grooves, wherein and a second recess structure of the plurality of recess structures may include one or more vacuum-distribution-grooves; and wherein the one or more vacuum-distribution-grooves of the recess structure are spatially separated from the one or more vacuum-distribution-grooves of the second recess structure.

Example 22 is the mounting system according to anyone of examples 1 to 21, wherein all recess structures of the plurality of recess structures are spatially separated from one another. For example, all recess structures of the plurality of recess may be disposed on a first side of the carrier plate.

Example 23 is the mounting system according to anyone of examples 1 to 22, wherein each holding area of the plurality of holding areas is spatially separated from the other holding areas of the plurality of holding areas.

Example 24 is the mounting system according to anyone of examples 1 to 23, which may further include: one or more covers to cover one or more recess structures of the plurality of recess structures. Thereby, the plurality of recess structures that have not received a coupon may be sealed so that the mounting system may be used even if not all recess structures are covered with a coupon.

Example 25 is the mounting system according to example 24, wherein the one or more covers are configured to be movable (e.g., slidable, tiltable) at the carrier plate (e.g., with respect to the carrier plate).

Example 26 is the mounting system according to anyone of examples 1 to 25, which may further include: a temperature control system to control an operation temperature of the carrier plate (e.g., of a first side of the carrier plate).

Example 27 is the mounting system according to example 26, wherein the temperature control system may include a heating system; and/or wherein the temperature control system may include a cooling system. For example, the heating system may be disposed within in the carrier plate. For example, the cooling system may be disposed within in the carrier plate.

Example 28 is the mounting system according to anyone of examples 1 to 27, wherein the carrier plate may include a semiconductor material, e.g., may be a semiconductor wafer.

Example 29 is the mounting system according to anyone of examples 1 to 28, wherein the carrier plate may include (e.g., may be substantially made of) steel (e.g., stainless steel as an example).

Example 30 is an mounting system to handle a plurality of coupons, the mounting system may include: a coupon adapter that may include a carrier plate that may include a plurality of recess structures disposed in the carrier plate, wherein each of the plurality of recess structures defines one holding area of a plurality of holding areas on the carrier plate to receive and hold a respective coupon; a vacuum distribution system at least partially disposed in the carrier plate, wherein the vacuum distribution system is configured to connect the plurality of recess structures to a vacuum supply system.

Example 31 is the mounting system according to example 30, that may further comprise a wafer chuck, wherein the coupon adapter is mounted on the wafer chuck.

Example 32 is the mounting system according to example 30 or 31, that may further include a vacuum supply system.

Example 33 is the mounting system according to example 32 or 32, wherein the vacuum distribution system may include one or more vacuum connection terminals to connect the vacuum distribution system to one or more vacuum traces of a wafer chuck (e.g., of the wafer chuck of example 31) and/or to a vacuum supply system. For example, the vacuum distribution system may include the one or more vacuum connection terminals to connect the vacuum distribution system to one or more vacuum traces of the wafer chuck of Example 31. For example, the vacuum distribution system may include the one or more vacuum connection terminals to connect the vacuum distribution system to the vacuum supply system of Example 32.

Example 34 is the mounting system according to example 30 or 31, wherein the vacuum distribution system further may include one or more vacuum channels that are at least partially in the carrier plate and configured to connect the plurality of recess structures to one or more vacuum traces of the wafer chuck.

Example 35 is the mounting system according to example 34, wherein a first vacuum channel of the one or more vacuum channels and a second vacuum channel of the one or more vacuum channels cross each other thereby forming a fluid-conductive junction.

Example 36 is the mounting system according to example 34 or 35, wherein a first vacuum channel of one or more vacuum channels extends from a first recess structure of the plurality of recess structures located on a first side of the carrier plate to a second side (e.g., a backside) of the carrier plate.

For example, the second side of the carrier plate may be laid onto the wafer chuck. For example, the second side may be opposite to the first side. For example, the first side may be a top side, and the second side may be a bottom side of the carrier plate.

Example 37 is the mounting system according to anyone of examples 34 to 36, wherein

a first vacuum channel of one or more vacuum channels may be configured to connect a first recess structure of the plurality of recess structures and a first vacuum connection terminals of the plurality of vacuum connection terminals to each other.

Example 38 is the mounting system according to anyone of examples 34 to 37, wherein a second vacuum channel of one or more vacuum channels may be configured to connect a second recess structure of the plurality of recess structures and a second vacuum connection terminal of the plurality of vacuum connection terminals to each other.

Example 39 is the mounting system according to example 38, wherein a third vacuum channel of the one or more vacuum channels may be configured to connect a third recess structure of the plurality of recess structures and the second vacuum connection terminal of the plurality of vacuum connection terminals to each other.

Example 40 is the mounting system according to anyone of examples 30 to 39, wherein the recess structures of the plurality of recess structures may be located on a first side (e.g., a top side) of the carrier plate. For example, the recess structures of the plurality of recess structures may be located on a first surface at the first side of the carrier plate.

Example 41 is the mounting system according to anyone of examples 30 to 40, which may further include: an alignment pattern (e.g., a coordinate system) to align the respective coupons relative to each other on the carrier plate.

Example 42 is the mounting system according to example 41, wherein the alignment pattern may include a plurality of alignment structures (e.g., one or more dots, one or more lines, as an example), and wherein one or more of the holding areas are arranged between two neighboring alignment structures of the plurality of alignment structures.

Example 43 is the mounting system according to anyone of examples 30 to 42, wherein a recess structure of the plurality of recess structures (e.g., all of the plurality of recess structures) may include one or more vacuum-distribution-grooves.

Example 44 is the mounting system according to example 43, wherein the one or more vacuum-distribution-grooves are formed in a circular, in a meander like shape, in an angular (e.g., cornered, rectangular) shape, in a circular shape or in a mixed shape thereof.

Example 45 is the mounting system according to anyone of examples 30 to 44, wherein a recess structure of the plurality of recess structures (e.g., all of the plurality of recess structures) may include a vacuum connection hole that is configured to connect the at least one recess structure (e.g., the one or more vacuum-distribution-grooves) to the vacuum distribution system (e.g., to one of the one or more vacuum channels).

Example 46 is the mounting system according to example 45, wherein the recess structure may have a total lateral extension measured along the carrier plate that may be greater than a lateral extension of the vacuum connection hole.

Example 47 is the mounting system according to anyone of examples 43 to 46, wherein each of the one or more vacuum-distribution-grooves may have a width that may be less than a lateral extension of the vacuum connection hole.

Example 48 is the mounting system according to anyone of examples 43 to 47, wherein a first vacuum-distribution-groove of the one or more vacuum-distribution-grooves may be connected to a second of the one or more vacuum-distribution-grooves only via the vacuum connection hole.

Example 49 is the mounting system according to anyone of examples 43 to 48, wherein the recess structure may include one or more vacuum-distribution-grooves, wherein and a second recess structure of the plurality of recess structures may include one or more vacuum-distribution-grooves; and wherein the one or more vacuum-distribution-grooves of the recess structure are spatially separated from the one or more vacuum-distribution-grooves of the second recess structure.

Example 50 is the mounting system according to anyone of examples 30 to 49, wherein all recess structures of the plurality of recess structures are spatially separated from one another. For example, all recess structures of the plurality of recess may be disposed on a first side of the carrier plate.

Example 51 is the mounting system according to anyone of examples 30 to 50, wherein each holding area of the plurality of holding areas is spatially separated from the other holding areas of the plurality of holding areas.

Example 52 is the mounting system according to anyone of examples 30 to 51, which may further include: one or more covers to cover one or more recess structures of the plurality of recess structures. This may allow to seal recess structures of the plurality of recess structures that have not received a coupon. For example, this may allow to use the chuck even if not all recess structures are covered with a coupon.

Example 53 is the mounting system according to example 52, wherein the one or more covers are configured to be movable (e.g., slidable, tiltable) at (e.g., with respect to) the carrier plate.

Example 54 is the mounting system according to anyone of examples 30 to 53, wherein the carrier plate may include a semiconductor material, e.g., may be a semiconductor wafer.

Example 55 is the mounting system according to anyone of examples 30 to 54, wherein the carrier plate may include (e.g., may be substantially made of) steel (e.g., stainless steel as an example).

Example 56 is a mounting system, which may include: a wafer chuck that may include a carrier plate having a first surface and one or more vacuum traces disposed within the first surface; and an coupon adapter configured to handle a plurality of coupons, the coupon adapter may include a carrier plate having a first surface and a second surface opposite to the first surface, a plurality of recess structures disposed in the first surface, wherein each of the plurality of recess structures defines a holding area at the first surface to receive and hold a respective coupon therein, the carrier plate may further include one or more vacuum connection terminals disposed at the second surface and a plurality of vacuum channels, (e.g., holes) each going through the carrier plate thereby forming a connection between the plurality of recess structures on the first surface and the one or more vacuum connection terminals on the second surface,; wherein the one or more vacuum connection terminals are arranged to fit to the one or more vacuum traces of the chuck.

Example 57 is a mounting system, which may include: a wafer chuck that may include a first surface and a one or more vacuum traces disposed on the first surface; and a coupon adapter to handle a plurality of coupons, the adapter may include: a carrier plate that may include a plurality of recess structures disposed in the carrier plate, wherein each of the plurality of recess structures defines one holding area of a plurality of holding areas on the carrier plate to receive and hold a respective coupon; a vacuum distribution system at least partially disposed in the carrier plate, wherein the vacuum distribution system is configured to connect the plurality of recess structures to a vacuum supply system.

Example 58 is the mounting system according to example to 57, which may further include a vacuum supply system.

Example 59 is a processing tool that may include a mounting system according to anyone of examples 1 to 58.

Example 60 is a method for processing, e.g., to testing, a plurality of coupons via a processing tool, the method may include: positioning a first coupon of the plurality of coupons in a first holding area of a carrier plate and positioning a second coupon of the plurality of coupons in a second holding area of the carrier plate, and supplying a vacuum to a first recess structure in the carrier plate defining the first holding area to fixate the first coupon covering the first recess structure and supplying a vacuum to a second recess structure in the carrier plate defining the second holding area to fixate the second coupon covering the second recess structure. The processing of each coupon of the plurality of coupons may be performed without remounting any coupon of the plurality of coupons. This may allow for processing the plurality of coupons without remounting any coupon of the plurality of coupons during the processing of the plurality of coupons.

Example 61 is the method according to example 60, which may further comprise sequentially processing the first coupon and the second coupon while both the first coupon and the second coupon are mounted on the carrier plate.

Example 62 is the method according to example 60, which may further include: positioning a cover on a third recess structure of the carrier plate to cover the third recess structure in the carrier plate to seal the third recess structure for avoiding a fluid flow into the third recess structure while supplying a vacuum to the third recess structure.

Example 63 is the method according to example 60 or 62, which may further include: positioning a cover in a third holding area of the carrier plate to cover a third recess structure in the carrier plate defining the third holding area to seal the third recess structure for avoiding a fluid flow into the third recess structure while supplying a vacuum to the third recess structure.

Example 64 is the method according anyone of examples 60 to 63, which may further include: controlling a vacuum supply to a plurality of recess structures in the carrier plate to supply the vacuum to the first recess structure and the second recess structure and to prevent a supply of the vacuum to one or more other recess structures in the carrier plate that are not covered by a coupon.

Example 65 is the method according to anyone of examples 60 to 64, which may further include: aligning the first coupon and the second coupon based on an alignment pattern disposed on the carrier plate.

Example 66 is the method according to anyone of examples 60 to 65, which may further include: heating and/or cooling the carrier plate to a predetermined temperature to control a temperature of the first coupon and the second coupon.

Example 67 is the method according to anyone of examples 60 to 66, wherein sequentially processing the first coupon and the second coupon may further comprise: determining a first orientation of the first coupon, rotating the carrier plate to a predefined angle based on the determined first orientation, processing the first coupon, determining a second orientation of the second coupon, rotating the carrier plate to a predefined angle based on the determined second orientation, and processing the second coupon.

Example 68 is the method according to example 67, wherein determining the first orientation and determining the second orientation may comprise an optical detection of the first coupon and the second coupon via a feature recognition system.

Example 69 is the method according to anyone of examples 60 to 68, wherein the first coupon and the second coupon may differ from one another with respect to at least one of shape and/or size.

Example 70 is the method according to anyone of examples 60 to 69, wherein the carrier plate may be an adapter plate configured to distribute a vacuum provided by a wafer chuck to the first recess structure and the second recess structure while being mounted at the wafer chuck, the method further comprising: mounting the carrier plate on a surface of the wafer chuck.

Example 71 is the method according to anyone of examples 60 to 70, which may further comprise: aligning the adapter plate, such that a vacuum connection terminal fits to a vacuum trace of the wafer chuck.

Example 72 is a control device configured to perform the method according to anyone of examples 60 to 71.

Example 73 is processor configured to perform the method according to anyone of examples 60 to 71.

Example 74 is a computer-readable storage medium comprising instructions which, when executed by a computer, cause the computer to carry out the method according to anyone of examples 60 to 71.

The terms “at least one” and “one or more” may be understood to include any integer number greater than or equal to one, i.e. one, two, three, four, [ . . . ], etc. The term “a plurality” or “a multiplicity” may be understood to include any integer number greater than or equal to two, i.e. two, three, four, five, [ . . . ], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The word “over”, used herein to describe forming a feature, e.g., a layer “over” a side or side, may be used to mean that the feature, e.g., the layer, may be formed “directly on”, e.g., in direct contact with, the implied side or side. The word “over”, used herein to describe forming a feature, e.g., a layer “over” a side or side, may be used to mean that the feature, e.g., the layer, may be formed “indirectly on” the implied side or side with one or more additional layers being arranged between the implied side or side and the formed layer.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A method for processing a plurality of coupons via a processing tool, the method comprising:
positioning a first coupon of the plurality of coupons in a first holding area of a carrier plate and positioning a second coupon of the plurality of coupons in a second holding area of the carrier plate;
supplying a vacuum to a first recess structure in the carrier plate defining the first holding area to fixate the first coupon covering the first recess structure and supplying a vacuum to a second recess structure in the carrier plate defining the second holding area to fixate the second coupon covering the second recess structure; and
sequentially processing the first coupon and the second coupon while both the first coupon and the second coupon are mounted on the carrier plate.

2. The method according to claim 1, further comprising
positioning a cover in a third holding area of the carrier plate to cover a third recess structure in the carrier plate defining the third holding area to seal the third recess structure for avoiding a fluid flow into the third recess structure while supplying a vacuum to the third recess structure.

3. The method according to claim 1, further comprising:
controlling a vacuum supply to a plurality of recess structures in the carrier plate to supply the vacuum to the first recess structure and the second recess structure and to prevent a supply of the vacuum to one or more other recess structures in the carrier plate that are not covered by a coupon.

4. The method according to claim 1, further comprising:
aligning the first coupon and the second coupon based on an alignment pattern disposed on the carrier plate.

5. The method according to claim 1, further comprising:
heating and/or cooling the carrier plate to a predetermined temperature to control a temperature of the first coupon and the second coupon.

6. The method according to claim 1,
wherein sequentially processing the first coupon and the second coupon comprises:
determining a first orientation of the first coupon, rotating the carrier plate to a predefined angle based on the determined first orientation, processing the first coupon, determining a second orientation of the second coupon, rotating the carrier plate to a predefined angle based on the determined second orientation, and processing the second coupon.

7. The method according to claim 6,
wherein determining the first orientation and determining the second orientation comprise an optical detection of the first coupon and the second coupon via a feature recognition system.

8. The method according to claim 1,
wherein the first coupon and the second coupon differ from one another with respect to at least one of shape and size.

9. The method according to claim 1, wherein the carrier plate is an adapter plate configured to distribute a vacuum provided by a wafer chuck to the first recess structure and the second recess structure while being mounted at the wafer chuck, the method further comprising:
mounting the carrier plate on a surface of the wafer chuck.

10. A mounting system comprising:
a coupon chuck, the coupon chuck comprising:
a carrier plate comprising a plurality of recess structures disposed in the carrier plate, wherein each of the plurality of recess structures defines one holding area of a plurality of holding areas on the carrier plate to receive and hold a respective coupon of a plurality of coupons, and
a vacuum distribution system disposed at least partially in the carrier plate and configured to connect the plurality of recess structures to a vacuum supply system.

11. The mounting system according to claim 10,
wherein the vacuum distribution system further comprises one or more vacuum connection terminals to connect the vacuum distribution system to a vacuum supply system.

12. The mounting system according to claim 10,
wherein the vacuum distribution system further comprises one or more vacuum channels disposed at least partially in the carrier plate and configured to connect the plurality of recess structures to a vacuum supply system.

13. The mounting system according to claim 10,
wherein a recess structure of the plurality of recess structures comprises one or more vacuum-distribution-grooves.

14. The mounting system according to claim 10,
wherein each recess structure of the plurality of recess structures comprises a vacuum connection hole that connects a respective recess structure to a corresponding one of a plurality of vacuum channels disposed in the carrier plate.

15. The mounting system according to claim 10,
wherein a first recess structure of the plurality of recess structures comprises one or more first vacuum-distribution-grooves and wherein a second recess structure of the plurality of recess structures comprises one or more second vacuum-distribution-grooves, and
wherein the one or more first vacuum-distribution-grooves are spatially separated from the one or more second vacuum-distribution-grooves.

16. The mounting system according to claim 10,
wherein the recess structures of the plurality of recess structures are spatially separated from one another; and/or
wherein each holding area of the plurality of holding areas is spatially separated from the other holding areas of the plurality of holding areas.

17. The mounting system according to claim 10, further comprising
one or more covers to cover one or more recess structures of the plurality of recess structures.

18. A mounting system comprising:
a coupon adapter, the coupon adapter comprising:
a carrier plate comprising a plurality of recess structures disposed in the carrier plate, wherein each of the plurality of recess structures defines one holding area of a plurality of holding areas on the carrier plate to receive and hold a respective coupon of a plurality of coupons, and
a vacuum distribution system at least partially disposed in the carrier plate, wherein the vacuum distribution system is configured to connect the plurality of recess structures to a vacuum supply system.

19. The mounting system according to claim 18, further comprising
a wafer chuck, wherein the coupon adapter is mounted on the wafer chuck.

20. The mounting system according to claim 18,
wherein the vacuum distribution system comprises one or more vacuum connection terminals to connect the vacuum distribution system to one or more vacuum traces of a wafer chuck; and
wherein the vacuum distribution system further comprises one or more vacuum channels disposed in the carrier plate and configured to connect the plurality of recess structures to the one or more vacuum connection terminals.
